(19) United States
(12) Patent Application Publication
(10) Pub. No.: US 2023/0073660 A1
(43) Pub. Date: Mar. 9, 2023

(54) SUBSTRATE PROCESSING APPARATUS

(71) Applicant: WONIK IPS CO., LTD., Pyeongtaek-si Gyeonggi-do (KR)

(72) Inventors: Sung Ho ROH, Yongin-si Gyeonggi-do (KR); Jung Hwan LEE, Osan-si Gyeonggi-do (KR); Cheong Hwan JEONG, Anseong-si Gyeonggi-do (KR); Tae Dong KIM, Osan-si Gyeonggi-do (KR); Young Jun KIM, Pyeongtaek-si Gyeonggi-do (KR); Moon Chul KUM, Gwangmyeong-si Gyeonggi-do (KR); Chan Soo PARK, Osan-si Gyeonggi-do (KR); Mi Sook KIM, Yongin-si Gyeonggi-do (KR); Yong Ki KIM, Hwaseong-si Gyeonggi-do (KR)

(73) Assignee: WONIK IPS CO., LTD., Pyeongtaek-si Gyeonggi-do (KR)

(21) Appl. No.: 17/901,252

(22) Filed: Sep. 1, 2022

(30) Foreign Application Priority Data
Sep. 2, 2021 (KR) 10-2021-0117026
Sep. 2, 2021 (KR) 10-2021-0117027
Sep. 2, 2021 (KR) 10-2021-0117028
Sep. 6, 2021 (KR) 10-2021-0118316
Jul. 27, 2022 (KR) 10-2022-0093308

(51) Int. Cl. C23C 16/458; C23C 16/455; C23C 16/52; C23C 16/44

(52) U.S. Cl. CPC C23C 16/4586; C23C 16/45563; C23C 16/52; C23C 16/4412

(57) ABSTRACT

The present invention disclosed herein relates to a substrate processing apparatus, and more particularly, to a substrate processing apparatus in which a substrate is processed at a high pressure and a low pressure. The present invention discloses a substrate processing apparatus including: a process chamber having an inner space; a substrate support on which a substrate is seated on a top surface thereof; an inner lid part which is installed to be vertically movable in the inner space and of which a portion is in close contact with the bottom surface of the process chamber to define a sealed processing space in which the substrate support is disposed; a gas supply part configured to supply a process gas to the processing space; and an inner lid driving part configured to drive the vertical movement of the inner lid part.

### CROSS-REFERENCE TO RELATED APPLICATIONS

This U.S. non-provisional patent application claims priority under 35 U.S.C. § 119(a) to Korean Patent Application No. 10-2021-0117028, filed on Sep. 2, 2021, Korean Patent Application No. 10-2021-0117026, filed on Sep. 2, 2021, Korean Patent Application No. 10-2021-0117027, filed on Sep. 2, 2021, Korean Patent Application No. 10-2021-0118316, filed on Sep. 6, 2021, and Korean Patent Application No. 10-2022-0093308, filed on Jul. 27, 2022, in the Korean Intellectual Property Office, the entire contents of which are hereby incorporated by reference.

### FIELD OF THE INVENTION

The present invention disclosed herein relates to a substrate processing apparatus, and more particularly, to a substrate processing apparatus in which a substrate is processed at a high pressure and a low pressure.

### BACKGROUND ART

The substrate processing apparatus may perform a process of processing a substrate such as a wafer, in general, perform etching, deposition, heat treatment, and the like on the substrate.

Here, when a film is formed on the substrate through the deposition, a process of removing impurities within the film and improving characteristics of the film after forming the thin film on the substrate is being required.

Particularly, as 3D semiconductor devices and substrates having a high aspect ratio appear, since a deposition temperature is lowered to meet a step coverage standard, or a gas having a high impurity content is inevitably used, the removing of the impurities within the film is becoming more difficult.

Accordingly, there is a need for a substrate processing method, which is capable of improving the characteristics of the thin film by removing the impurities existing in the thin film without deterioration in characteristics of the thin film after forming the thin film on the substrate, and an apparatus for processing the substrate, which performs the method.

In addition, there is a limitation that the deposited thin film is contaminated by a small amount of impurities, which remain in a chamber as well as the thin film on the substrate, and thus, it is necessary to remove the impurities from the inside of the chamber including a substrate support that supports the substrate.

To improve this limitation, Korean Patent Application No. 10-2021-0045294A, which is the related art, disclosures a substrate processing method, in which high-pressure and low-pressure atmospheres are repeatedly formed to reduce imperfection on a surface of a substrate and the inside of a chamber, thereby improving characteristics of a thin film.

However, when the above-described substrate processing method is applied to the substrate processing apparatus according to the related art, since a volume of a processing space for processing a substrate is relatively large to cause a limitation that it is difficult to realize a fast pressure change rate.

In addition, the substrate processing apparatus according to the related art has a limitation in that it is difficult to implement a process of repeatedly performing a wide pressure range from a low pressure of about 0.01 Torrs to a high pressure of about 5 Bars within a short time.

In addition, the substrate processing apparatus according to the related art has a limitation in that it is difficult to perform high-pressure substrate processing and secure durability of a gate valve because the gate valve that seals the processing space does not withstand the pressure when performing the high-pressure substrate processing.

However, when the corresponding process is performed through the substrate processing apparatus according to the related art, as the pressure in the processing space in which the substrate is processed is rapidly changed, a temperature change occurs, and thus, as such a temperature change is not actively controlled, there is a limitation in that completeness of substrate processing is deteriorated.

More specifically, when the substrate is heated through the substrate support supporting the substrate, there are limitations in that heat transfer efficiency is deteriorated due to indirect contact between a processing surface of the substrate and a heater, a heat loss occurs due to proximity between the substrate support and a bottom surface of the process chamber, a temperature of the substrate is not controlled in response to the rapidly changing temperature due to characteristics of the installed heater.

To solve the limitations, the volume of the processing space is minimized in the substrate processing apparatus according to the related art. However, there is a limitation that an influence of the gas according to a gas injection part is very large because a distance between the substrate and the gas injection part supplying the gas is adjacent due to the minimized volume of the processing space.

Particularly, as uniform gas supply to the substrate is not achieved through the gas injection part, the temperature of the substrate is locally lowered, and a processing rate thereof is changed, resulting in a limitation in that the uniformity of substrate processing is deteriorated.

### SUMMARY OF THE INVENTION

To solve the above-mentioned limitations, an object of the present invention is to provide a substrate processing apparatus, which is capable of minimizing a volume of a processing space to improve a pressure change rate in a wide pressure range.

In addition, to solve the above-mentioned limitations, another object of the present invention is to provide a substrate processing apparatus, which is capable of easily controlling a temperature of a substrate to uniformly supply a gas to the substrate.

In accordance with an embodiment of the present invention, a substrate processing apparatus includes: a process chamber 100 including a chamber body 110 which has an opened upper portion, in which an installation groove 130 is defined at a central side of a bottom surface 120 thereof, and which includes a gate 111 configured to load/unload a substrate 1 is disposed at one side thereof, and a top lid 140 coupled to the upper portion of the chamber body 110 to define an inner space S1; a substrate support 200 installed to be inserted into the installation groove 130 of the chamber body 110 and having a top surface on which the substrate 1 is seated; an inner lid part 300 which is installed to be vertically movable in the inner space S1 and of which a portion is in close contact with the bottom surface 120 adjacent to the installation groove 130 through descending to define a sealed processing space S2 in which the substrate support 200 is disposed; a gas supply part 400 installed to communicate with the processing space S2 and configured to supply a process gas to the processing space S2; and an inner lid driving part 600 installed to pass through the top lid 140 to drive the vertical movement of the inner lid part 300.

The bottom surface 120 may be disposed higher than a top surface of the substrate 1 seated on the substrate support 200.

The installation groove 130 may be provided in a shape corresponding to the substrate support 200 installed so that the processing space S2 is minimized.

The substrate support 200 may include: a substrate support plate 210 which has a planar circular shape and on which the substrate 1 is seated on the top surface thereof; and a substrate support post 220 passing through a bottom surface of the installation groove 130 so as to be connected to the substrate support plate 210, wherein the installation groove 130 may have a shape corresponding to the substrate support plate 210 to minimize a remaining space except for a space in which the substrate support plate 210 is installed.

The substrate processing apparatus may further include a sealing part 900 provided on either the bottom surface of the inner lid part 300 or the bottom surface 120 at a position at which the inner lid part 300 and the bottom surface 120 are in close contact with each other.

The sealing part 900 may include a first sealing member 910 provided along the edge of the bottom surface of the inner lid part 300 and a second sealing member 920 provided at a position spaced a predetermined distance from the first sealing member 910.

The substrate processing apparatus may further include a pumping part 500 installed to be in close contact with the inner lid part 300 in the process chamber 100 to pump the sealing part 900.

The pumping part 500 may pump an interspace S3 between the first sealing member 910 and the second sealing member 920.

The gas supply part 400 may be installed adjacent to an edge of the substrate support 200.

The processing space S2 may be defined between a portion of the bottom surface of the inner lid part 300 and the top surface connecting the gas supply part 400 to the substrate support 200.

The gas supply part 400 may include: a gas injection part 430 installed at the edge of the installation groove 130 to inject the process gas; and a gas supply passage 420 provided to pass through the bottom surface of the process chamber 100 so as to supply the process gas to the gas injection part 430 from the outside.

The inner lid driving part 600 may include: a plurality of driving rods 610, each of which one end passes through the top surface of the process chamber 100 and is coupled to the inner lid part 300; and at least one driving source 620 connected to the other end of each of the plurality of driving rods 610 to drive the driving rods 610 vertically.

The inner lead driving part 600 may further include a bellows 630 installed to surround the driving rod 610 between the top surface of the process chamber 100 and the inner lid part 300.

The gas supply part 400 may include: a gas injection part 430 defining a first diffusion space S5 in which the process gas is diffused; and a plurality of gas injection holes 440 defined in the gas injection part 430 to inject the process gas to the processing space S2.

The gas injection part 430 may be provided in an annular shape to be installed along the edge of the substrate support 200.

The process chamber 100 may include a supply passage 190 provided to pass through the bottom surface so as to communicate with the first diffusion space S5 and configured to transfer the process gas to the first diffusion space S5 from the outside, and the gas injection part 430 may include a first diffusion groove 431 for the first diffusion space S5 in a bottom surface thereof to communicate with the supply passage 190.

The gas injection part 430 may have the first diffusion space S5 therein and include a through-hole 432 defined in a position corresponding to the supply passage 190 on the bottom surface to receive the process gas from the supply passage 190.

The gas injection holes 440 may be defined in a top surface of the gas injection part 430.

The gas injection holes 440 may be reduced step by step or gradually in size as the gas injection holes 440 are adjacent to the supply passage 190.

The gas injection holes 440 may be step by step or gradually away from the adjacent gas injection holes 440 as the gas injection holes 440 are adjacent to the supply passage 190.

The gas injection holes 440 may be disposed symmetrically with respect to a center of the substrate support 200 on a plane.

The gas injection part 430 may have a top surface with an inclination that increases toward the edge.

The substrate processing apparatus may further include a gas diffusion part 1000 that is disposed between the gas supply part 400 and the process chamber 100 to diffuse the process gas transferred to the gas supply part 400 by providing a second diffusion space S6.

A second diffusion groove 1010 may be defined in a bottom surface of the gas diffusion part 1000 to define the second diffusion space S6 together with the process chamber 100.

The gas supply part 400 may further include a first coupling member 450 passing through the gas injection part 430 so as to be coupled to the gas diffusion part 1000.

The process chamber 100 may include a first stepped part 191 provided to have a height difference so that a portion of the gas diffusion portion 1000 is inserted, or a portion of the supply passage 190 is inserted into the second diffusion groove 1010.

The gas injection part 430 may be installed on the top surface of the gas diffusion part 1000 to define the first diffusion space S5 together with the top surface of the gas diffusion part 1000, and the gas diffusion part 1000 may include at least one gas transfer hole 1020 defined in the top surface to transfer the process gas from the second diffusion space S6 to the first diffusion space S5.

The gas diffusion part 1000 may include a second stepped part 1030 so that a portion thereof is inserted into the first diffusion groove 431.

The gas transfer hole 1020 may be provided in plurality and may be arranged point-symmetrically with respect to a center of the substrate support 200 on a plane.

A plurality of the gas diffusion part 1000 may be stacked between the process chamber 100 and the gas injection part 430.

The substrate processing apparatus may further include a temperature adjusting part 1100 installed in the inner lid part 300 to adjust a temperature of the substrate 1 disposed in the processing space S2.

The substrate support 200 may include: a substrate support plate 210 on which the substrate 1 is seated on a top surface; a substrate support post 220 passing through the bottom of the installation groove 130 so as to be connected to the substrate support plate 210; and an internal heater 230 installed inside the substrate support plate 210.

The temperature adjusting part 1100 may include: a temperature adjusting plate 1110 installed in the inner lid part 300 to heat or cool the substrate 1; and a rod part 1120 passing through the top lid 140 so as to be coupled to the temperature adjusting plate 1110.

The temperature adjusting plate 1110 may be installed in a through-hole 320 defined in a central side of the inner lid part 300 corresponding to the substrate 1.

The temperature adjusting part 1100 may further include a buffer plate 1130 configured to cover the through-hole 320 at a lower side of the inner lid part 300.

The temperature adjusting plate 1110 may include at least two temperature adjusting areas that are separated from each other on a plane and are independently adjustable in temperature.

The substrate processing apparatus may further include a controller for controlling the heating or cooling of the temperature adjusting part 1100, wherein the controller may control the temperature adjusting part 1100 so that the temperature of the substrate 1 or the processing space S2 is constantly maintained while a pressure of the processing space S2 is changed.

The temperature adjusting part 1100 may further include a cover plate 1140 installed to cover the through-hole 320 at an upper side of the inner lid part 300.

The temperature adjusting plate 1110 may be installed at a position opposite to the substrate 1 on the bottom surfaces of the inner lid part 300.

The temperature adjusting part 1100 may be a halogen or LED heater configured to heat the substrate 1.

The temperature adjusting plate 1110 may be installed to be inserted into an insertion groove 330 defined at the central side of the top surface of the inner lid part 300 corresponding to the substrate 1.

The temperature adjusting areas may include: a first temperature adjusting area 1111 that shares a center with the planar circular temperature adjusting plate 1110 and is divided into a planar circular shape at a position corresponding to the central side of the substrate 1; a third temperature adjusting area 1113 separated from an edge of the temperature adjusting plate 1110; and a second temperature adjusting area 1112 divided between the first temperature adjusting area 1111 and the third temperature adjusting area 1113 area.

The substrate processing apparatus may further include a controller for controlling the heating or cooling of the temperature adjusting part 1100, wherein the controller the third temperature adjusting area 1113 to have a temperature higher than that of the first temperature adjusting area 1111.

A substrate processing method according to the present invention, which processes a substrate using a substrate processing apparatus including a process chamber 100 which defines an inner space and on which a gate 111 is provided at one side, a substrate support 200 having a top surface on which a substrate 1 is seated, and an inner lid part 300 that is opposite to the substrate support 200 and is installed to be vertically movable in the inner space, the substrate processing method includes: a substrate loading process (S100) of loading the substrate 1 into the inner space through the gate 111 by a transfer robot provided at the outside; a processing space forming process (S200) of allowing a portion of the inner lid part 300 to descend so as to be in close contact with a bottom surface 120 of the process chamber in a state in which the substrate 1 is seated on the substrate support 200 through the substrate loading process (S100), thereby dividing the inner space into a sealed processing space S2 and other non-processing space S3; and a substrate processing process (S300) of performing substrate processing on the substrate 1 disposed in the processing space S2.

The substrate processing method may further include: after the substrate is processed through the substrate processing process (S300), a processing space releasing process (S400) of allowing the inner lid part 300 to ascend so as to release the sealed processing space S2; and a substrate unloading process (S500) of unloading the processed substrate 1 by the transfer robot, which is disposed at the outside, from the inner space to the outside.

The substrate loading process (S100), the processing space forming process (S200), the substrate processing process (S300), the processing space releasing process (S400), and the substrate unloading process (S500) may be sequentially and repeatedly performed several times.

The substrate processing method may further include, before the substrate 1 is loaded into the inner space through the substrate loading process (S100), a cleaning process of supplying a gas through a side of the processing space S2 in the state in which the inner lid part 300 ascends to exhaust the gas through a side of the non-processing space S3.

The substrate processing process (S300) may include: a pressure rising process (S310) of raising a pressure in the processing space S2 to a first pressure higher than a normal pressure, and a pressure falling process (S320) of falling the pressure of the processing space S2 from the first pressure to a second pressure.

The second pressure may be a pressure lower than the normal pressure.

The pressure falling process (S320) may include: a first pressure falling process (S321) of falling the pressure of the processing space S2 from the first pressure to the normal pressure, and a second pressure falling process (S322) of falling the pressure of the processing space S2 from the normal pressure to the second pressure lower than the normal pressure.

In the substrate processing process (S300), a pressure of the non-processing space S3 may be constantly maintained at a vacuum pressure lower than the normal pressure.

The processing space releasing process (S400) may include: a pressure adjusting process (S410) of adjusting a pressure of at least one of the non-processing space S3 or the processing space S2 to adjust a pressure difference between the non-processing space S3 and the processing space S2 to a pressure within a preset range; and an inner lid ascending process (S420) of allowing the inner lid part 300 to ascend so as to release the processing space S2.

In the pressure adjusting process (S410), the pressures of the non-processing space S3 and the processing space S2 may be adjusted to be equal to each other.

The process chamber 100 may further includes a gate valve 150 configured to open and close the gate 111, wherein the substrate processing method may further include, after the processing space forming process (S200), a gas closing process of closing the gate 111 through the gate valve 150 to seal the inner space.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a cross-sectional view illustrating a substrate processing apparatus according to the present invention;

FIG. 2 is a cross-sectional view illustrating a processing space of the substrate processing apparatus of FIG. 1;

FIG. 3 is an enlarged view illustrating a portion A that shows am O-ring of FIG. 1;

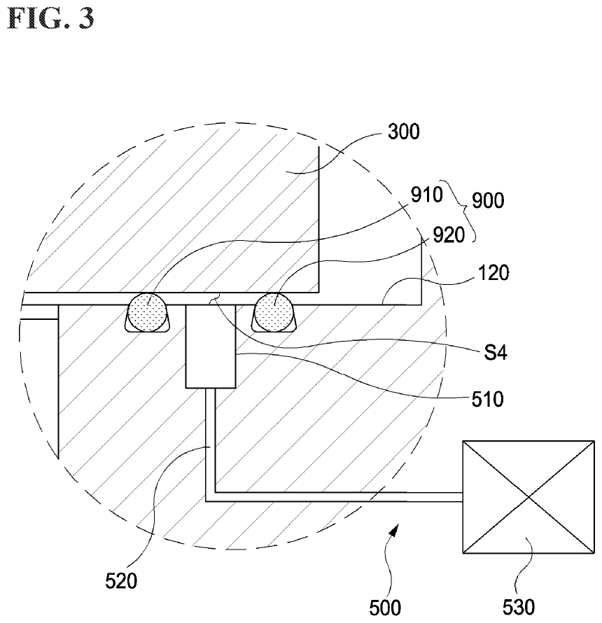

FIG. 4 is a graph illustrating a change in pressure according to a process through the substrate processing apparatus of FIG. 1.

FIG. 5 is a cross-sectional view illustrating another example of the substrate processing apparatus according to the present invention;

FIG. 6 is a cross-sectional view illustrating a temperature adjusting part of the substrate processing apparatus of FIG. 5;

FIG. 7 is a cross-sectional view illustrating another example of the temperature adjusting part of the substrate processing apparatus of FIG. 5;

FIG. 8 is a cross-sectional view illustrating divided temperature adjusting areas of the temperature adjusting part in the substrate processing apparatus of FIG. 5;

FIG. 9 is a graph illustrating a pressure change in a processing space and a non-processing space through the substrate processing apparatus of FIG. 5;

FIG. 10 is a cross-sectional view illustrating another example of the substrate processing apparatus according to the present invention;

FIG. 11 is an exploded perspective view illustrating a gas supply part and a gas diffusion part of the substrate processing apparatus of FIG. 10;

FIG. 12 is an exploded perspective view illustrating bottom surfaces of the gas supply part and the gas diffusion part of the substrate processing apparatus of FIG. 10 in a direction of a bottom surface;

FIG. 13 is an enlarged cross-sectional view illustrating the gas supply part and the gas diffusion part of the substrate processing apparatus of FIG. 10;

FIG. 14 is an exploded cross-sectional view illustrating another example of the gas supply part and the gas diffusion part of the substrate processing apparatus of FIG. 10;

FIG. 15 is an exploded cross-sectional view illustrating another example of the gas supply part and the gas diffusion part of the substrate processing apparatus of FIG. 10;

FIG. 16 is a cross-sectional view illustrating another example of the substrate processing apparatus according to the present invention;

FIG. 17 is a flowchart illustrating a substrate processing method using the substrate processing apparatus according to the present invention;

FIG. 18 is a flowchart illustrating a substrate processing process of the substrate processing method of FIG. 17; and

FIG. 19 is a flowchart illustrating a processing space releasing process of the substrate processing method of FIG. 17.

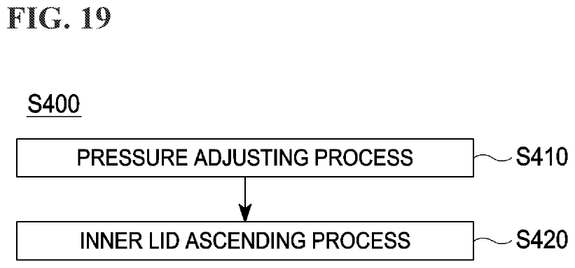

### DETAILED DESCRIPTION OF THE PREFERRED EMBODIMENTS

Hereinafter, a substrate processing apparatus according to the present invention will be described with reference to the accompanying drawings.

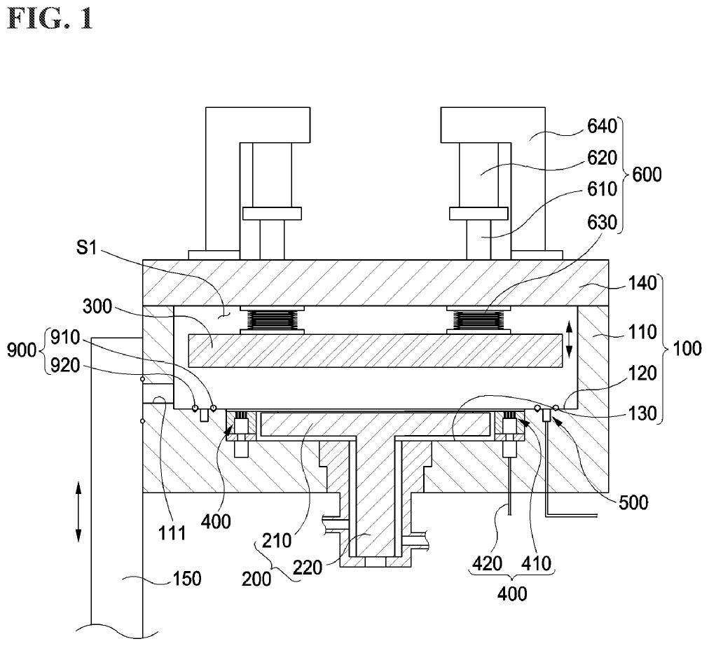

As illustrated in FIG. 1, a substrate processing apparatus according to the present invention may include: a process chamber 100 including a chamber body 110 which has an opened upper portion, in which an installation groove 130 is defined at a central side of a bottom surface 120 thereof, and which includes a gate 111 configured to load/unload a substrate 1 is disposed at one side thereof, and a top lid 140 coupled to the upper portion of the chamber body 110 to define an inner space S1; a substrate support 200 installed to be inserted into the installation groove 130 of the chamber body 110 and having a top surface on which the substrate 1 is seated; an inner lid part 300 which is installed to be vertically movable in the inner space S1 and of which a portion is in close contact with the bottom surface 120 adjacent to the installation groove 130 through descending to define a sealed processing space S2 in which the substrate support 200 is disposed; a gas supply part 400 installed to communicate with the processing space S2 and configured to supply a process gas to the processing space S2; and an inner lid driving part 600 installed to pass through the top lid 140 to drive the vertical movement of the inner lid part 300.

In addition, the substrate processing apparatus according to the present invention may further include a pumping part 500 installed to be in close contact with the inner lid part 300 in the process chamber 100 to pump a gas leaking into the sealing part 900.

In addition, the substrate processing apparatus according to the present invention may include a charging member 700 installed between an inner surface of the substrate support 200 and the installation groove 130 to occupy at least a portion of a space between the substrate support 200 and the inner surface of the installation groove 130.

In addition, the substrate processing apparatus according to the present invention may further include a substrate support pin part 800 configured to support the substrate 1 loaded into and unloaded from the process chamber 100 and seated on the substrate support 200.

In addition, the substrate processing apparatus according to the present invention may include a temperature adjusting part 1100 installed in the inner lid part 300 to adjust a temperature of the substrate 1 disposed in the processing space S2.

Here, the substrate 1 to be processed may be understood to include all substrates such as substrates used in display devices such as LCD, LED, and OLED, semiconductor substrates, solar cell substrates, glass substrates, and the like.

The process chamber 100 may have a configuration in which the inner space S1 is defined therein and thus may have various configurations.

For example, the process chamber 100 may include the chamber body 110 having the opened upper portion and the top lid 140 covering the opened upper portion of the chamber body 110 to define the sealed inner space S1 together with the chamber body 110.

In addition, the process chamber 100 may include the bottom surface 120 defining the bottom of the inner space S1 and the installation groove 130 defined in the bottom surface 120 to install the substrate support 200.

In addition, the process chamber 100 may further include a gate valve 150 for opening and closing a gate 111 provided at one side of the chamber body 110 to load and unload the substrate 1.

In addition, the process chamber 100 may further include a support pin installation groove 160 defined in a bottom surface of the substrate support 200 to be described later to install a substrate support ring 820.

The chamber body 110 may have an opened upper portion to define the sealed inner space S1 together with the top lid 140 to be described later.

Here, the chamber body 110 may be made of a metal material including aluminum. As another example, the chamber body 110 may be made of a quartz material and may have a rectangular parallelepiped shape like the chamber that is disclosed in the related art.

The inner space S1 may be divided into a processing space S2 and a non-processing space S3 that is a space except for the processing space S2 through an inner lid part 300 to be described later.

The top lid 140 may be coupled to the upper side of the chamber body 110 having the opened upper portion and may be configured to define the sealed inner space S1 together with the chamber body 110.

Here, the top lid 140 may be provided in a rectangular shape on a plane to correspond to the shape of the chamber body 110 and may be made of the same material as the chamber body 110.

In addition, the top lid 140 may have a plurality of through-holes so that the inner lid driving part 600 to be described later is installed to pass therethrough, and an end of a first bellows 630 to be described later may be coupled to the top lid 140 to prevent various gases and foreign substances from leaking.

The configuration of the top lid 140 may be omitted, and the chamber body 110 may be integrally provided to define the sealed inner space S1 therein.

The process chamber 100 may include the bottom surface 120, of which an inner bottom surface defines the bottom of the inner space S1, and the installation groove 130 defined to install the substrate support 200.

More specifically, as illustrated in FIG. 1, in the process chamber 100, the installation groove 130 may be defined with a height difference at a central side of the bottom surface to correspond to the substrate support 200 to be described later, and the bottom surface 120 may be defined on an edge of the installation groove 130.

That is, in the process chamber 100, the installation groove 130 for installing the substrate support 200 may be defined with the height difference in the inner bottom surface, and the other portion may be defined as the bottom surface 120 at a height higher than the installation groove 130.

The gate valve 150 may have a configuration for opening and closing the gate 111 disposed at one side of the chamber body 110 to load and unload the substrate 1 and may have various configurations.

Here, the gate valve 150 may be in close contact with or released from the chamber body 110 through vertical driving and forward/backward driving to open or close the gate 111. For another example, the gate valve 150 may open or close the gate 111 through single driving in a diagonal direction. In this process, various types of driving methods disclosed in the related art, such as a cylinder, a can, an electromagnetism, and the like may be applied.

The support pin installation groove 160 may have a configuration for installing the substrate support 800 that supports the substrate 1 and is seated on the substrate support 200 or spaced upward from the substrate support 200 to support the substrate 1 to load or unload the substrate 1 and may have various configurations.

For example, the support pin installation groove 160 may be provided as a planar annular groove corresponding to the substrate support ring 820 so that a substrate support ring 820 to be described later is installed.

Here, the support pin installation groove 160 may be installed to correspond to a position at which the substrate support ring 820 is installed on the bottom surface of the process chamber 100, and more specifically, may be defined in the installation groove 130.

That is, the support pin installation groove 160 may be defined in the installation groove 130 defined with the height difference from the bottom surface 120 and may have a predetermined depth so that the substrate support ring 820 is movable vertically in the installed state.

Thus, in the support pin installation groove 160, the substrate support ring 820 may be installed so that a plurality of substrate support pins 810 are installed to pass through the filling member 700 and the substrate support plate 210 upward.

Since the support pin installation groove 160 is defined in the installation groove 130 to define a predetermined volume, the volume of the processing space S2 defined by the inner lid part 300 to be described later may increase.

To solve this limitation, the filling member 700 may be installed in the installation groove 130 to cover the support pin installation groove 160, thereby blocking a space defined by the processing space S2 and the support pin installation groove 160. As a result, the processing space S2 may be defined in minimum volume.

More specifically, if there is no support pin installation groove 160, since a space for the substrate support pin 810 and the substrate support ring 820 to be described later is separately required under the substrate support plate 210, an increase of a dead volume may occur. Thus, to remove the dead volume, the support pin installation groove 160 may be defined so that the substrate support pin 810 and the substrate support ring 820 are inserted therein when descending.

Unlike this, the support pin installation groove 160 may not be installed in the bottom surface 120 of the process chamber 100, but may be defined in the filling member 700 installed in the installation groove 130.

That is, the support pin installation groove 160 may be defined to a predetermined depth in the top surface of the filling member 700, more specifically, to a depth at which the substrate support ring 820 and the substrate support pin 810 are inserted and thus may ascend to support the substrate 1 in a state of being inserted into the filling member 700.

Here, the substrate support pin 810 may be installed to pass through the filling member 700.

The substrate support 200 may have a configuration that is installed in the process chamber 100 so that the substrate 1 is seated on a top surface thereof and may have various configurations.

That is, the substrate support 200 may support the substrate 1 to be processed by seating the substrate 1 on the top surface thereof and may be fixed during the substrate processing process.

In addition, the substrate support 200 may include a heater therein to provide a temperature atmosphere in the processing space S2 for the substrate processing.

For example, the substrate support 200 may include a substrate support plate 210 on which the substrate 1 is seated on a top surface thereof, a substrate support post 220 passing through the bottom of the installation groove 130 so as to be connected to the substrate support plate 210, and the internal heater 230 installed in the substrate support plate 210.

The substrate support plate 210 may have a configuration in which the substrate 1 is seated on the top surface thereof and may be provided as a plate having a planar circular shape corresponding to the shape of the substrate 1.

Here, the substrate support plate 210 may be provided with the internal heater 230 therein to create a process temperature for the substrate processing in the processing space S2. Here, the process temperature may be about 400° C. to 550° C.

The substrate support post 220 may have a configuration that passes through the bottom surface of the process chamber 100 so as to be connected to the substrate support plate 210 and may have various configurations.

The substrate support post 220 may pass through the bottom surface of the process chamber 100 so as to be coupled to the substrate support plate 210, and various conductors for supplying power to the internal heater 230 may be installed in the substrate support post 220.

The internal heater 230 may have a configuration that is installed inside the substrate support plate 210 to heat the processing space S2 and the substrate 1 so as to process the substrate 1.

Here, the internal heater 230, any type of heater disclosed in the related art may be applied, and for example, the internal heater 230 may be provided in the substrate support plate 210 and may be provided in the form of a heating wire that generates heat through power received from the outside.

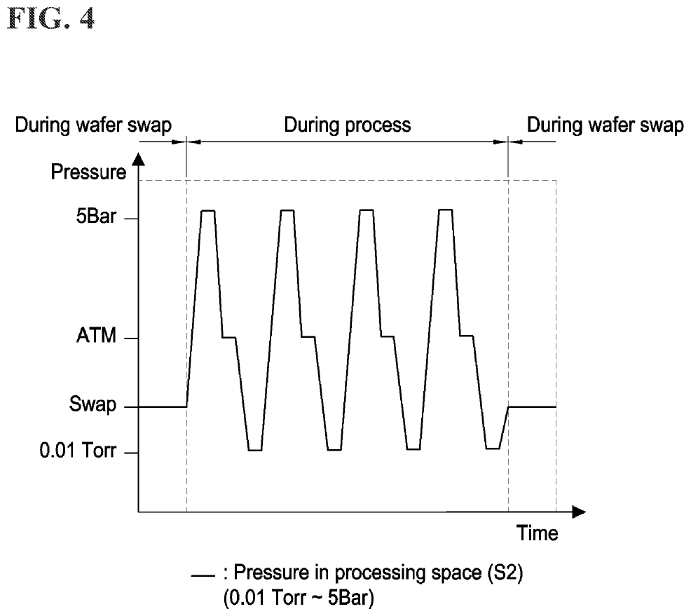

As illustrated in FIG. 4, the substrate processing apparatus according to the present invention may be an apparatus for performing the substrate processing in which a high-pressure and low-pressure atmosphere is repeatedly changed and created within a short time, and more particularly, it is necessary to repeatedly change a pressure range of about 0.01 Torrs at a pressure change rate of about 1 Bar/s.

However, when considering a vast space volume of the inner space S1 of the chamber body 110, the above-described pressure change rate may not be achieved, and thus, there is a need to minimize the volume of the processing space S2 for the substrate processing.

For this, the substrate processing apparatus according to the present invention includes an inner lid part 300 which is installed to be vertically movable in the inner space S1 and of which a portion is in close contact with the process chamber 100 through descending to define the sealed processing space S2, in which the substrate support 200 is disposed.

The inner lid part 300 may have a configuration which is installed to be vertically movable in the inner space S1 and of which a portion is in close contact with the process chamber 100 through the descending to define the sealed processing space S2, in which the substrate support 200 is disposed.

That is, the inner lid part 300 may be installed to be vertically movable at an upper side of the substrate support 200 in the inner space S1 so as to be in close contact with at least a portion of the inner surface of the process chamber 110 through the descending, and thus, the inner space S1 may be divided into the processing space S2, which is sealed between the inner lid part 300 and an inner lower surface of the process chamber 100, and the non-processing space S3 except for the processing space S2.

Thus, the substrate support 200 may be disposed in the processing space S2 to perform the substrate processing on the substrate 1 seated on the substrate support 200 in the processing space S2 having the minimized volume.

For example, an edge of the inner lid part 300 may be in close contact with the bottom surface 120 through the descending to define the sealed processing space S2 between the bottom surface and the inner bottom surface of the process chamber 100.

For another example, the edge of the inner lid part 300 may be in close contact with the inner surface of the process chamber 100 through the descending to define the sealed processing space S2.

The edge of the inner lid part 300 may be in close contact with the bottom surface 120 through the descending to define the sealed processing space S2, and the substrate support 200 installed in the installation groove 130 may be disposed within the processing space S2.

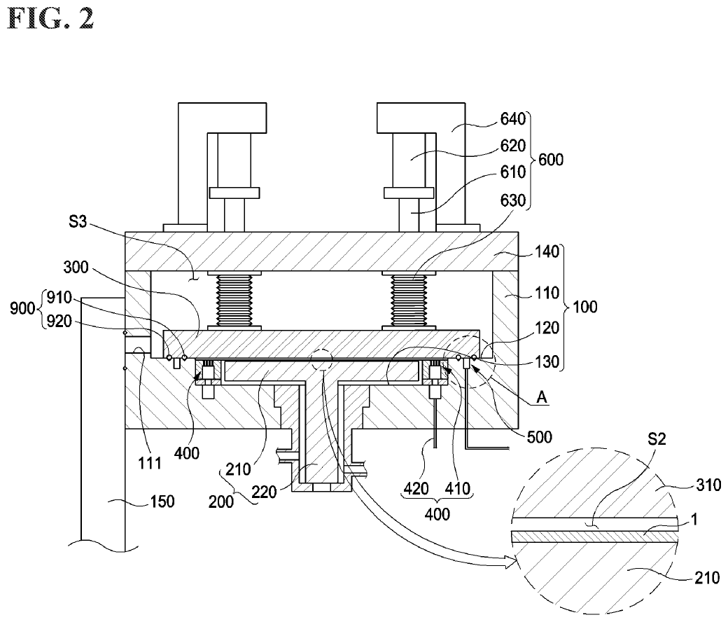

That is, as illustrated in FIG. 2, the edge of the inner lid part 300 may be in close contact with the bottom surface 120 disposed at a high position with a height difference with respect to the installation groove through the descending to define the sealed processing space S2 between the bottom surface and the installation groove 130.

Here, the substrate support 200, more specifically, the substrate support plate 210 and the filling member 700 may be installed in the installation groove 130 to minimize the volume of the processing space S2 and dispose the substrate 1 to be processed on the top surface thereof.

In this process, to minimize the volume of the processing space S2, the installation groove 130 may have a shape corresponding to the substrate support 200 installed in the processing space S2, more particularly, may be provided as a groove having a cylindrical shape corresponding to the circular substrate support plate 210.

That is, the installation groove 130 may have a shape corresponding to that of the substrate support plate 210 so that a remaining space except for the space, in which the substrate support plate 210 and the filling member 700 are installed, in the installation space, in which the installation groove 130 is defined, is minimized.

In this process, to prevent an interference between the substrate 1 seated on the top surface of the substrate support plate 210 and the inner lid part 300 from occurring, the bottom surface 120 may be disposed at a height higher than that of the top surface of the substrate 1 seated on the substrate support 200.

It means that, as a distance between the substrate 1 seated on the substrate support 200 and the bottom surface of the inner lid part 300 increases, the processing space S2 increases also in volume. Thus, the height of the bottom surface 120 may be set at a position at which the distance is minimized while preventing the interference between the substrate 1 and the inner lid part 300 from occurring.

The inner lid part 300 may include an inner lid 310 that moves vertically through an inner lid driving part 600.

The inner lid 310 may have a configuration that is vertically movable in the inner space through the inner lid driving part 600 and may have various configurations.

Here, the inner lid 310 may cover the installation groove 130 on a plane, and the edge of the inner lid part 300 may have a size corresponding to a portion of the bottom surface 120. In addition, the edge may be in close contact with the bottom surface 120 to define the sealed processing space S2 between the installation groove 130 and the inner lid part 300.

For another example, the edge of the inner lid 310 may be in close contact with the inner surface of the process chamber 100 to define the processing space S2.

In addition, to effectively achieve and maintain the process temperature in the sealed processing space S2 defined according to the vertical movement, the inner lid 310 may be made of a material having an excellent thermal insulation effect that is capable of preventing the temperature of the processing space S2 from being lost to the inner space.

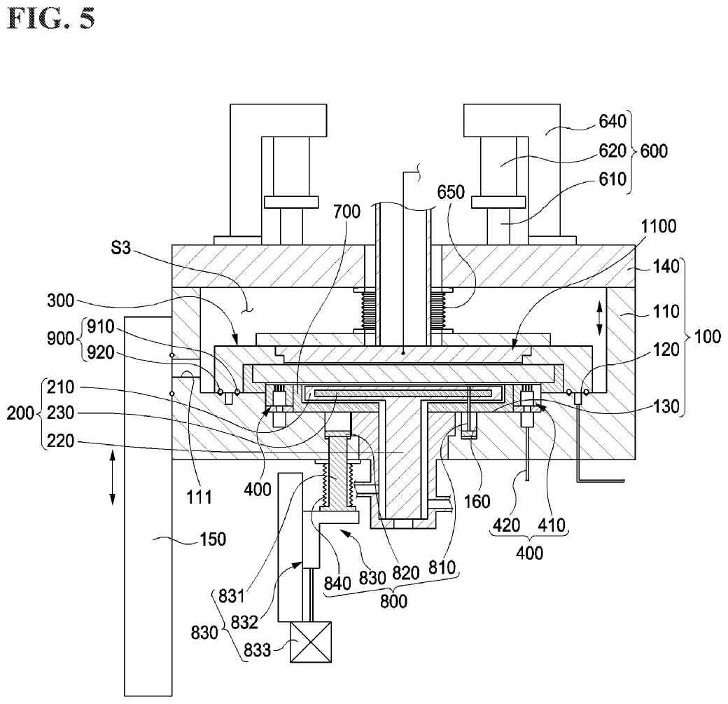

In addition, as illustrated in FIG. 5, the inner lid part 300 may have a configuration in which a temperature adjusting part 1100 to be described later is installed.

Here, the inner lid part 300 may have a through-hole 320 defined in a central side so that a temperature adjusting part 1100 to be described later, more specifically, a temperature adjusting plate 1110 and a buffer plate 1130 are installed. In addition, the temperature adjusting plate 1110 may be installed in the through-hole 320 from an upper side.

More specifically, the through-hole 320 may be defined at a position of the inner lid 310 opposite to the substrate 1 and the substrate support plate 210 so that the temperature adjusting plate 1110 is installed.

Here, to support the temperature adjusting plate 1110, a support stepped part 340 may be provided at an upper side of the through-hole 320 in a radial direction of the inner lid 310, and an end of the temperature adjusting plate 1110 may be supported on the support stepped part 340 so that the temperature adjusting plate 1110 is stably supported and installed in the through-hole 320.

For another example, as illustrated in FIG. 5, the inner lid part 300 may have an insertion groove 330 defined in a top surface thereof so that the temperature adjusting plate 1110 to be described later is inserted and installed therein.

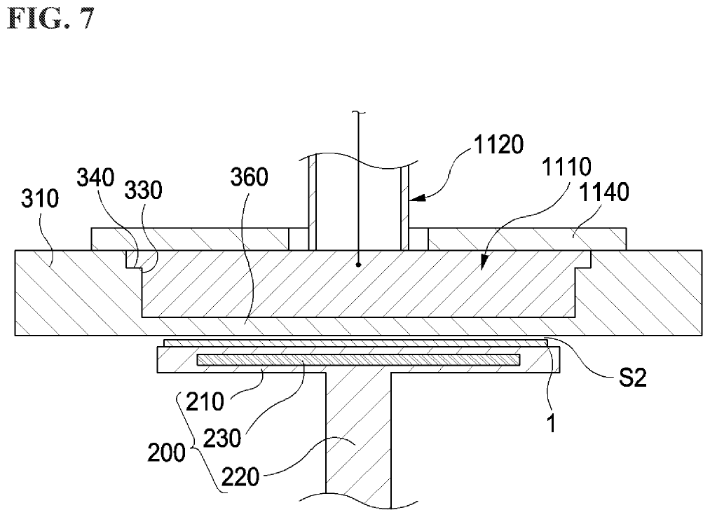

That is, unlike the above-described structure, as illustrated in FIG. 7, the inner lid 310 may have the simple insertion groove 330 in the top surface thereof so that the temperature adjusting plate 1110 is inserted into the insertion groove 330. Here, the insertion groove 330 may be defined at the central side of the inner lid 310 that is a position opposite to the substrate 1 and the substrate support 200.

In this case as well, as described above, the support stepped part 340 may also be provided at the upper side of the insertion groove 330 in the radial direction of the inner lid 310 to support the temperature adjusting plate 1110 inserted and installed in the insertion groove 330.

Furthermore, at this time, in the inner lid 310, a lower portion 360 of the insertion groove 330 may be made of a transparent material so that heat supplied through the temperature adjusting plate 1110 or heat provided from the processing space S2 to the temperature adjusting plate 1110 is easily transferred.

That is, the inner lid 310 may pass through the lower portion 360 of the insertion groove 330 to perform the heat exchange with the substrate 1 and the processing space S2. Thus, when considering that the temperature adjusting plate 1110 uses a heat supply method using an LED heater or a halogen heater, the lower portion 360 may be partially made of the transparent material through which heat is easily transferred.

The sealing part 900 may have a configuration provided on at least one of the inner lid part 300 or the bottom surface 120 of the process chamber 100 and may be provided to correspond to a position at which the bottom surface 120 of the processing chamber 100 and the inner lid part 300 are in close contact with each other.

That is, when the edge of the inner lid part 300 is in close contact with the bottom surface 120 to define the sealed processing space S2, the sealing part 900 may be provided along an edge of the bottom surface of the inner lid part 300 so as to be in contact with the bottom surface 120.

Thus, the sealing part 900 may induce the formation of the sealed processing space S2 and prevent a process gas of the processing space S2 from leaking to the outside of the inner space S1.

For example, the sealing part 900 may include a first sealing member 910 provided along the edge of the bottom surface of the inner lid part 300 and a second sealing member 920 provided at a position spaced a predetermined distance from the first sealing member 910.

Here, each of the first sealing member 910 and the second sealing member 920 may be an O-ring according to the related art, and the first sealing member 910 and the second sealing member 920 may be installed to be spaced a predetermined distance from each other along the edge of the bottom surface of the inner lid part 300.

That is, the first sealing member 910 and the second sealing member 920 may perform double sealing on the processing space S2 to prevent the process gas from leaking from the processing space S2 to the outside.

The sealing part 900 may be installed by being inserted into an insertion groove provided in the bottom surface 120 and may be in close contact with or separated from the inner lid part 300 according to the vertical movement of the inner lid part 300.

For another example, the sealing part 900 may also be provided on the bottom surface of the inner lid part 300.

The pumping part 500 may have a configuration which is installed at a position that is in close contact with the inner lid part 300 of the process chamber 100 to pump the process gas leaking to the sealing part 900 and may have various configurations.

For example, the pumping part 500 may be installed to pass through the bottom surface of the process chamber 100 at a position corresponding to the close contact position between the inner lid part 300 and the process chamber 100 to pump the sealing part 900 installed on the inner led part 300.

That is, the pumping part 500 may minimize exposure of the process gas to the sealing part 900, which is a consumable, to minimize corrosion and damage of the sealing part 900 exposed to the processing space S2, in which a high temperature is generated, and the process gas is used, thereby improving durability.

For this, the pumping part 500 may pump an interspace S4 between the first sealing member 910 and the second sealing member 920.

For example, the pumping part 500 may include a pump 530 provided at the side to pump the interspace S4, a pumping nozzle 510 installed at a position corresponding between the first sealing member 910 and the sealing member 920, and a pumping passage 520 provided to pass through the bottom surface of the process chamber 100 so that one end thereof communicates with the pumping nozzle 510, and the other end thereof is connected to the external pump 530.

Here, the pumping nozzle 510 may be provided in a planar circular shape along the sealing part 900. For another example, the pumping nozzle 510 may be provided at a portion of the groove defined in the bottom surface of the process chamber 100 along the sealing part 900 to perform the pumping along the groove.

The pumping passage 520 may be a separate pipe configuration provided to pass through the bottom surface of the process chamber 100. For another example, the pumping passage 520 may be provided by processing the bottom surface of the process chamber 100.

Unlike the above-described example of pumping the process gas leaking into the sealing part 900, the pumping part 500 may have a configuration that supplies a purge gas into the interspace S4 between the first sealing member 910 and the second sealing member 920.

The gas supply part 400 may communicate with the processing space S2 to supply the process gas to the processing space S2 and may have various configurations.

For example, as illustrated in FIG. 1, the gas supply part 400 may include a gas supply nozzle 410 exposed to the processing space S2 to supply the process gas into the processing space S2 and a gas supply passage 420 passing through the process chamber 100 so as to be connected to the gas supply nozzle 410 and transfer the process gas supplied through the gas supply nozzle 410.

Here, as illustrated in FIG. 2, the gas supply part 400 may be installed to be adjacent to the substrate support 200 on the edge of the installation groove 130 to supply the process gas to the processing space S2.

The processing space S2 may be defined between a portion of the bottom surface of the inner lid part 300 and the top surfaces of the gas supply part 400 and the substrate support 200.

The gas supply nozzle 410 may have a configuration that is exposed to the processing space S2 to supply the process gas into the processing space S2 and may have various configurations.

For example, the gas supply nozzle 410 may be installed to be adjacent to a side surface of the substrate support plate 210 on the edge of the installation groove 130 and may inject the process gas upward or toward the substrate support plate 210 to supply the process gas into the processing space S2.

Here, the gas supply nozzle 410 may be provided to surround the substrate support plate 210 on the edge of the installation groove 130 and may inject the process gas from at least a portion of the side surface of the substrate support plate 210 on the plane.

For example, the gas supply nozzle 410 may inject the process gas from the edge of the installation groove 130 toward the bottom surface of the inner lid part 300 and may supply the process gas to generate a desired pressure within a short time in the processing space S2 according to the minimized volume of the processing space S2.

The gas supply passage 420 may pass through the bottom surface of the process chamber 100 so as to be connected to an external process gas storage part and may receive the process gas to supply the process gas to the process gas supply nozzle 410.

Here, the gas supply passage 420 may be a pipe installed to pass through the bottom surface of the process chamber 100. For another example, the gas supply passage 420 may be provided by processing the bottom surface of the process chamber 100.

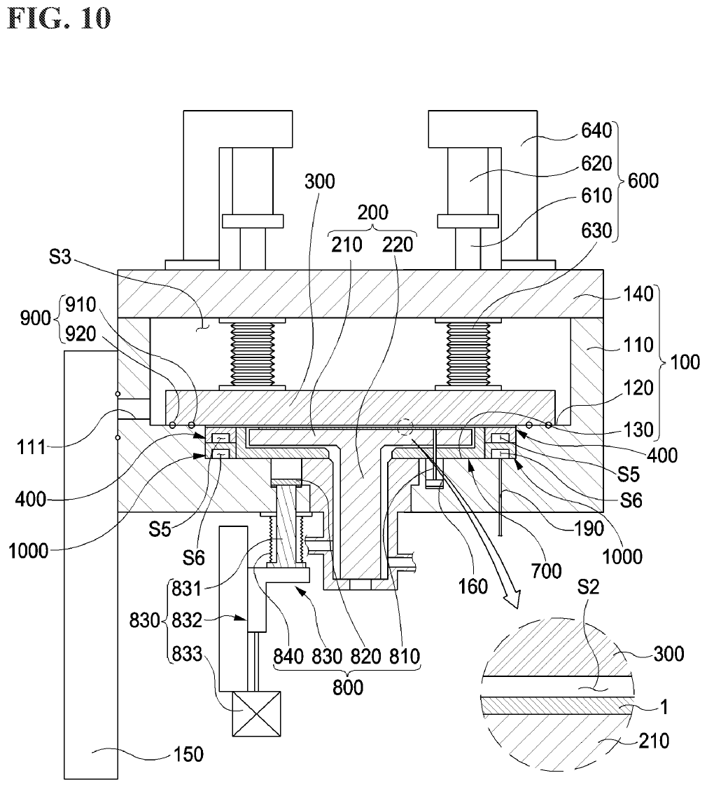

For another example, as illustrated in FIG. 10, the gas supply part 400 may include a gas injection part 430 defining a first diffusion space S5 in which the process gas is diffused and a plurality of gas injection holes 440 defined in the gas injection part 430 to inject the process gas to the processing space S2.

The gas supply part 400 may further include a first coupling member 450 passing through the gas injection part 430 so as to be coupled to the gas diffusion part 1000.

Here, the process chamber 100 may include a supply passage 190 that is provided to pass through the bottom surface, communicates with the first diffusion space S5, and transfers the process gas from the outside to the first diffusion space S5.

The supply passage 190 may have a configuration corresponding to the above-described gas supply passage 420 and also may have a configuration that passes through the process chamber 100 to transfer the process gas from the outside to the first diffusion space S5.

The supply passage 190 may pass through the bottom surface of the process chamber 100 so as to be connected to an external process gas storage part and may receive the process gas to supply the process gas to the process gas supply part 400 to be described later.

Here, the supply passage 190 may be provided as a pipe installed to pass through the bottom surface of the process chamber 100. For another example, the gas supply passage 420 may be provided by processing the bottom surface of the process chamber 100.

In addition, the supply passage 190 may be provided at at least one position of the positions adjacent to the edge of the substrate 1 on which the gas supply part 400 to be described later is installed on the bottom surface of the process chamber 100.

Thus, the gas supply part 400 may have a configuration in which the first diffusion space S5 communicating with the above-described supply passage 190 is defined to diffuse the supplied process gas and inject the supplied process gas into the processing space S2.

The gas injection part 430 may be provided in an annular shape to be installed along the edge of the substrate support 200 and may be installed to surround the edge of the substrate support 200, i.e., the substrate 1.

Thus, the gas injection part 430 may inject the process gas into the processing space S2 from the edge that is closest to the substrate 1.

The gas injection part 430 may be installed to surround the edge of the substrate support 200, i.e., the substrate 1 and may also be installed on an inner wall surface of the above-described installation groove 130 to pass through in a vertical direction and then be installed to be fixed through a plurality of second coupling members (not shown) coupled to the process chamber 100.

Here, the gas injection part 430 may have a first diffusion groove 431 for the first diffusion space S5 in a bottom surface thereof.

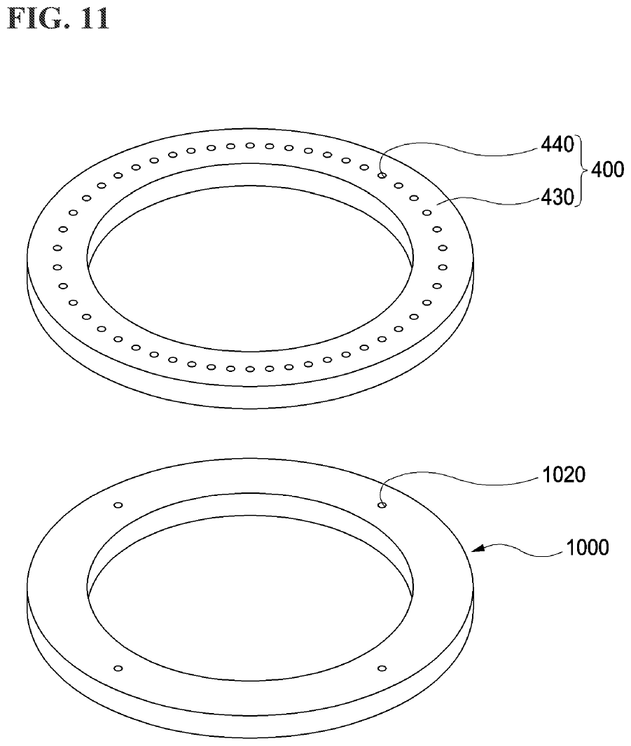

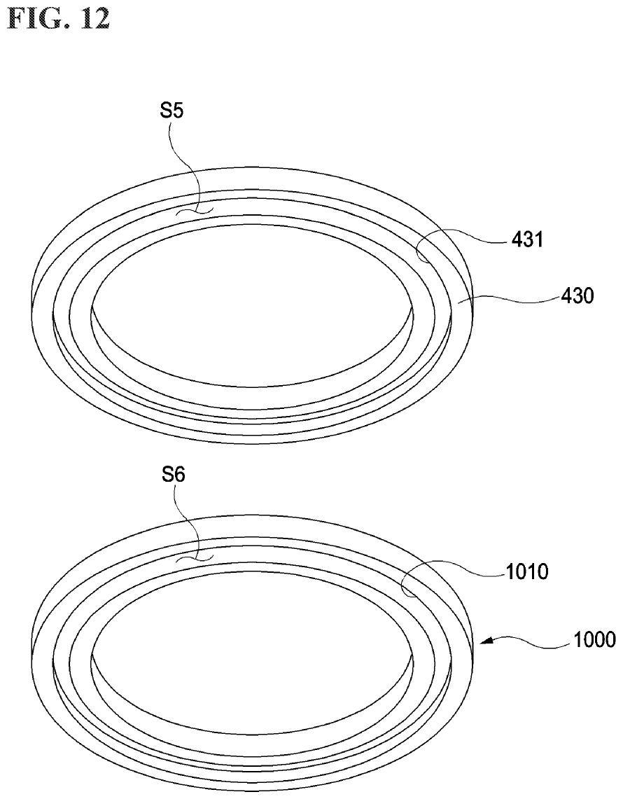

For example, as illustrated in FIGS. 11 and 12, the gas injection part 430 may have an annular configuration and may be provided in an annular shape corresponding to the first diffusion groove 431 in the bottom surface thereof. Thus, the bottom surface of the bottom surface 100 and the top surface of the gas diffusion part 1000 may be disposed on the bottom surface of the gas injection part 430 to cover the first diffusion groove 431, thereby defining the first diffusion space S5.

Here, in the gas injection part 430, a plurality of gas injection holes 440 to be described later may be defined in the top surface to inject the process gas to the processing space S2. Here, the top surface may be provided as a horizontal plane.

Thus, the gas injection part 430 may not directly inject the process gas toward the substrate 1, but directly inject the process gas toward the bottom surface of the inner lid part 300 defining the processing space S2 to flow to the substrate 1, thereby minimizing an influence on the substrate 1 according to an injection pressure and temperature of the process gas.

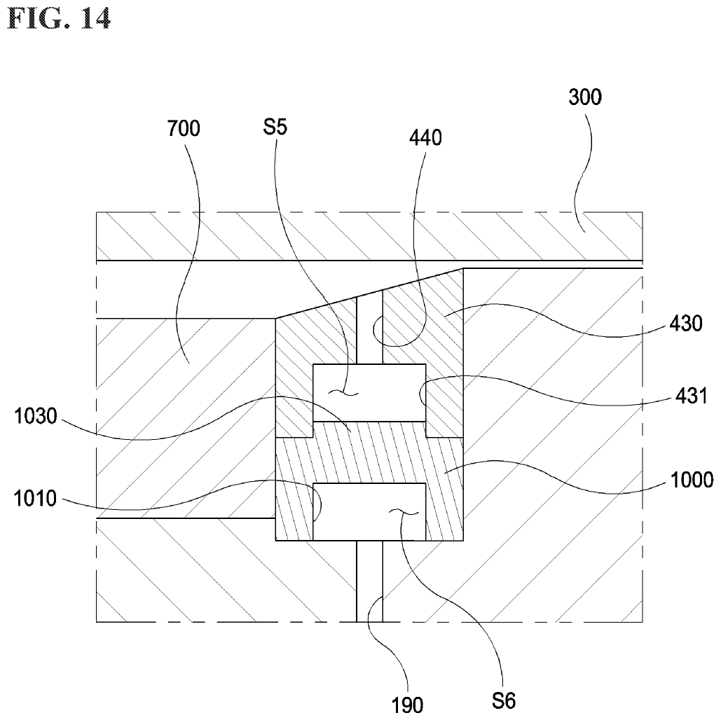

In addition, for another example, as illustrated in FIG. 14, the top surface may have an inclination that increases toward the edge. In addition, the plurality of gas injection holes 440 may be defined in the top surface, and thus, the process gas may be smoothly injected toward the substrate 1 in the processing space S2.

That is, the gas injection part 430 may inject the process gas in a direction toward the upper substrate 1 without injecting the process gas in the upper vertical direction as the inclination is provided on the top surface.

The gas injection part 430 may be provided to have an inclination of which the top surface becomes lower toward the edge.

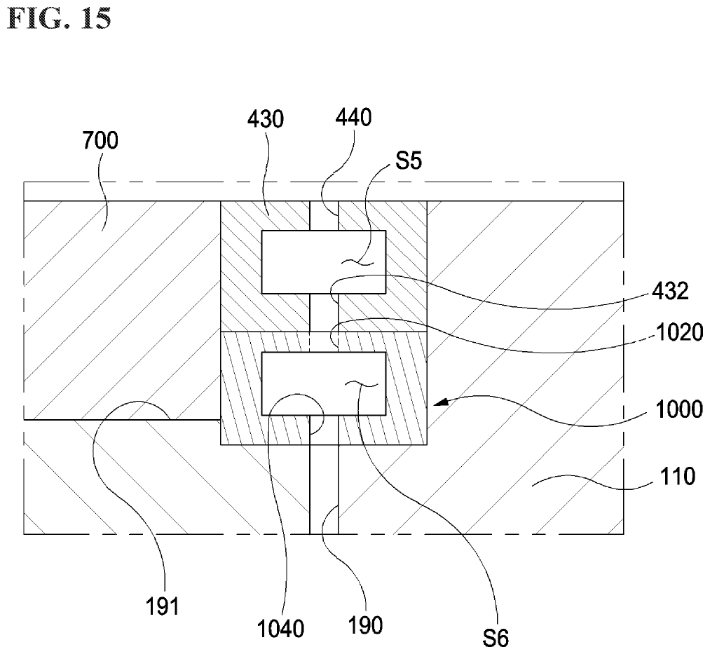

In addition, for another example, as illustrated in FIG. 15, in the gas injection part 430, the first diffusion space S5 may be defined therein, and in order to receive the process gas from the supply passage 190, the gas injection part 430 may include a through-hole 432 defined at a position corresponding to the supply passage 190 on the bottom surface.

That is, the gas injection part 430 may have a configuration in which the first diffusion space S5 is defined therein, and a through-hole 432 may be defined at a position, which corresponds to the gas transfer hole 1020, of the top surface of the supply passage 190 or the gas diffusion part 1000 to be described later so that the process gas is supplied to the first diffusion space S5.

In this case, the gas injection part 430 may be manufactured by coupling a cover part (not shown), which covers the bottom surface, through welding or the like in a state in which the first diffusion groove 431 is defined as described above, thereby prevent the process gas from leaking toward the substrate support 200 between the gas injection part 430 and the top surface of the gas diffusion part 1000.

The gas injection holes 440 may have a configuration that is defined in the gas injection part 430 to inject the process gas into the processing space S2 and may be provided in plurality.

In this case, the plurality of the gas injection holes 440 may be defined in the top surface of the gas injection part 430, and the plurality of the gas injection holes 440 may be defined at the same interval and size based on the annular gas injection part 430.

That is, the gas injection holes 440 may be disposed point-symmetrically with respect to a center of substrate support 200 on the plane.

In addition, for another example, the gas injection holes 440 may be provided to have a size that decreases step by step or gradually toward the supply passage 190 in consideration of the supply passage 190 provided in a single number at one side of the edge with respect to the substrate support 200 to realize the uniform process gas injection.

That is, an injection amount of process gas through the gas injection hole 440 disposed at a position adjacent to the supply passage 190 on the plane may be greater than that of process gas through the gas injection hole 440 disposed at a position far from the supply passage 190. Here, to correct the this, the size and arrangement of the gas injection hole 440 may be appropriately adjusted.

Thus, the gas injection holes 440 may be defined so that the size of the hole is reduced step by step or gradually as the gas injection hole 440 approaches the supply passage 190. For another example, the gas injection holes 440 may be defined so that a distance from the adjacent gas injection holes 440 increases step by step or gradually as the gas injection holes 440 approach the adjacent supply passage 190.

The gas diffusion part 1000 may have a configuration that is disposed between the gas supply part 400 and the process chamber 100 and has a second diffusion space S6 to diffuse the process gas transferred to the gas supply part 400, and may have various configurations.

That is, the gas diffusion part 1000 may have a configuration that is disposed between the gas supply part 400 and the supply passage 190, receives the process gas from the supply passage 190 to performs primary diffusion, and transfers the diffused process gas to the gas supply part 400.

In this case, the gas diffusion part 1000 may be provided in a single number, and for another example, a plurality of gas diffusion parts 1000 may be stacked to induce additional diffusion.

A second diffusion groove 1010 may be defined in a bottom surface of the gas diffusion part 1000 to define the second diffusion space S6 together with the process chamber 100.

In addition, the gas diffusion part 1000 may include at least one gas transfer hole 1020 defined in the top surface to transfer the process gas from the second diffusion space S6 to the first diffusion space S5.

In addition, the gas diffusion part 1000 may include a second stepped part 1030 so that a portion thereof is inserted into the first diffusion groove 431.

The gas diffusion part 1000 may have a configuration similar to the above-described gas supply part 400 and may be provided in an annular shape to surround the edge of the substrate support 200, and the gas supply part 400 may be stacked on the top surface and thus may have a corresponding planar shape and size.

The second diffusion groove 1010 may have a configuration defined in the bottom surface of the gas diffusion part 1000 to define the second diffusion space S6 together with the process chamber 100 and may have an annular bottom shape as a whole, like the first diffusion groove 431.

That is, the second diffusion groove 1010 may be covered through the process chamber 100 to define the second diffusion space S6.

For another example, as illustrated in FIG. 15, in the gas diffusion part 1000, the second diffusion space S6 may be defined therein, and in order to receive the process gas from the supply passage 190, the gas injection part 430 may include a gas inflow hole 1040 defined at a position corresponding to the supply passage 190 on the bottom surface.

That is, the gas diffusion part 1000 may have a configuration in which the second diffusion space S6 is defined therein, and the gas inflow hole 1040 may be defined at a position, which corresponds to the gas transfer hole 1020, of the top surface of the supply passage 190 so that the process gas is supplied to the second diffusion space S6.

In this case, the gas diffusion part 1000 may be manufactured by coupling a cover part (not shown), which covers the bottom surface, through welding or the like in a state in which the second diffusion groove 1010 is defined as described above, thereby prevent the process gas from leaking toward the substrate support 200 on the contact surface between the gas diffusion part 1000 and the process chamber 100.

The gas transfer hole 1020 may have a configuration defined to transfer the process gas from the second diffusion space S6 to the first diffusion space S5 on the top surface of the gas diffusion part 1000, and at least one, more preferably, a plurality of gas transfer holes 1020 may be provided.

In this case, the gas transfer holes 1020 may be arranged point-symmetrically with respect to the center of the substrate support 200 on the plane and may be spaced apart from each other at the same distance.

In addition, for another example, like the gas injection hole 440 described above, the gas injection holes 440 may be provided asymmetrically in consideration of the supply passage 190.

The second stepped part 1030 may have a configuration that protrudes from the top surface of the gas diffusion part 1000 to provide a height difference so that a portion thereof is inserted into the first diffusion groove 431 on the top surface.

That is, the second stepped part 1030 may protrude from the top surface to provide the height difference and may be inserted into the first diffusion groove 431. As a result, the height difference may be provided between the contact portion between the gas diffusion portion 1000 and the gas supply portion 400 and the first diffusion space S5 to minimize the leakage of the process gas.

In addition, a first stepped part 191 having a height difference on the bottom surface 120 of the corresponding process chamber 100 may be provided so that a portion of the gas diffusion part 1000 is inserted, or a portion of the supply passage 190 is inserted into the second diffusion groove 1010.

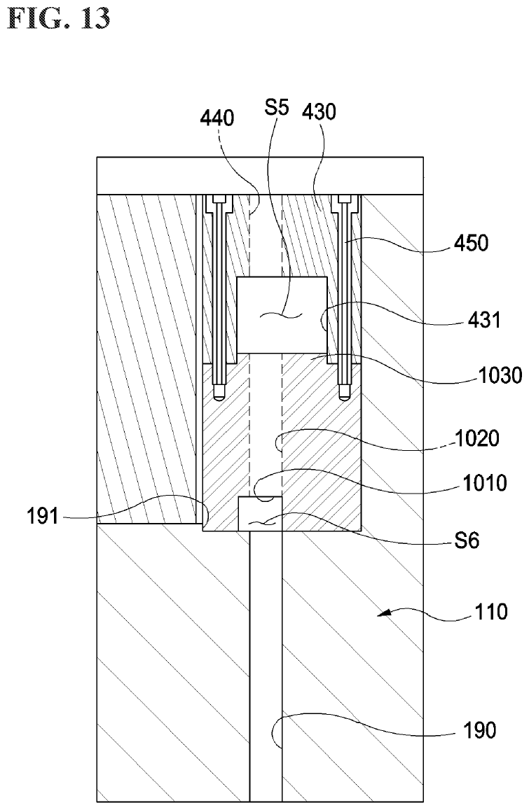

That is, as illustrated in FIG. 13, the first stepped part 191 may be disposed on the bottom surface 120 so that a portion of the gas diffusion part 1000 is inserted, thereby preventing the process gas from leaking from the second diffusion space S6 between the gas diffusion part 1000 and the process chamber 100.

In addition, for another example, in the first stepped part 191, the bottom surface 120 in which the supply passage 190 is provided may protrude and then be inserted into the second diffusion groove 1010 to provide a height difference on the contact surface between the gas diffusion part 1000 and the process chamber 100, thereby preventing the process gas from leaking from the second diffusion space S6.

The inner lid driving part 600 may be installed to pass through the top surface of the process chamber 100 so as to drive the vertical movement of the inner lid part 300 and may have various configurations.

For example, the inner lid driving part 600 may include a plurality of driving rods 610, each of which one end passes through the top surface of the process chamber 100 and is coupled to the inner lid part 300, and at least one driving source 620 connected to the other end of each of the plurality of driving rods 610 to drive the driving rods 610 vertically.

In addition, the inner lid driving part 600 may include a fixing support 630 installed on the top surface of the process chamber 100, i.e., the top lid 140 to fix and support the end of the driving rod 610 and a first bellows 630 installed to surround the driving rod 610 between the top surface of the process chamber 100 and the inner lid part 300.

In addition, since the rod part 1120 of the temperature adjusting part 1100 to be described later moves vertically according to the vertical movement of the inner lid part 300, the rod part 1120 may be installed to pass through the top lid 140 to cause the gas leakage. As a result, the inner lid driving part 600 may include a second bellows 650 installed to surround the rod part 1120 to prevent the gas from leaking to the outside.

The driving rod 610 may have a configuration having one end passing through the top surface of the process chamber 100 so as to be coupled to the inner lid part 300 and the other end coupled to the driving source 620 outside the process chamber 100 to drive the inner lid part 300 vertically through the vertical movement due to the driving source 620.

Here, the driving rod 610 may be provided in plurality, more particularly, two or four to be coupled to the top surface of the inner lid part 300 at a predetermined interval so that the inner lid part 300 moves vertically while being maintained horizontally.

The driving source 620 may have a configuration that vertically drives the driving rod 610 installed and coupled to the fixing support 640 and may have various configurations.

The driving source 620 may be applied to any configuration as long as it is driving method that is disclosed in the related art, for example, various driving methods such as a cylinder method, an electromagnetic driving, screw motor driving, cam driving, and the like may be applied.

The first bellows 630 may have a configuration that is installed to surround the driving rod 610 between the top surface of the process chamber 100 and the inner lid part 300 to prevent the gas in the inner space S1 from leaking thought the top surface of the process chamber 100.

Here, the first bellows 630 may be installed in consideration of the vertical movement of the inner lid part 300.

The second bellows 650 may be installed so that one end thereof is coupled to a cover plate 1140 to be described later, and the other end thereof is coupled to the bottom surface of the top lid 140 to surrounds the rod part 1120, thereby preventing the gas from leaking through the top lid 140 passing through the rod part 1120 even in the vertical movement of the inner lid part 300 and the temperature adjusting plate 1110.

The temperature adjusting part 1100 may have a configuration that is installed in the inner lid part 300 to adjust the temperature of the substrate 1 disposed in the processing space S2 together with the internal heater 230, and may have various configurations.

That is, the temperature adjusting part 1100 may have a configuration that heats or cools the substrate 1 so as to adjust the temperature of the processing space S2 and the substrate 1 together with the internal heater 230.

For example, as illustrated in FIG. 5, the temperature adjusting part 1100 may include the temperature adjusting plate 1110 installed in the inner lid part 300 to heat or cool the substrate 1 and the rod part 1120 passing through the top lid 140 so as to be coupled to the temperature adjusting plate 1110.

In addition, the temperature adjusting part 1100 may further include a buffer plate 1130 coupled to the through-hole 320 at the lower side of the inner lid part 300 to cover the temperature adjusting plate 1110.

In addition, the temperature adjusting part 1100 may further include a cover plate 1140 installed to cover the through-hole 320 at the upper side of the inner lid part 300.

The temperature adjusting plate 1110 may have a configuration that is installed on the inner lid part 300 to heat or cool the substrate 1, and may have various configurations.

For example, the temperature adjusting plate 1110 may be installed in the through-hole 320 defined in the inner lid 310 as described above to heat or cool the substrate 1.

The above-described internal heater 230 may be configured to supply heat to the substrate 1 and the processing space S2 through the substrate support plate 210 due to heating of a heating element through power supply, and an initial heating time may take a long time, and there is a limitation in that it is difficult to immediately respond to a rapid temperature change.

Thus, the temperature adjusting plate 1110 may have a configuration for immediately supplying heat to the substrate 1 within a short time, and for example, a halogen or LED heater may be applied.

In addition, the temperature adjusting plate 1110 may have a cooling passage defined therein to immediately cool the substrate 1 within a short time, thereby cooling the substrate 1 through circulation of a refrigerant.

The temperature adjusting plate 1110 may have a height difference on the edge thereof. As described above, the temperature adjusting plate 1110 may be supported and installed on the support stepped part 340 disposed in the through-hole 320 of the inner lid 310.

Furthermore, for another example, the temperature adjusting plate 1110 may be installed on the bottom surface of the inner lid 310 to be directly exposed to the substrate 1 through simple attachment, coupling, or the like.

In addition, the temperature adjusting plate 1110 may include at least two temperature adjusting areas that are separated from each other on a plane and are independently adjustable in temperature.

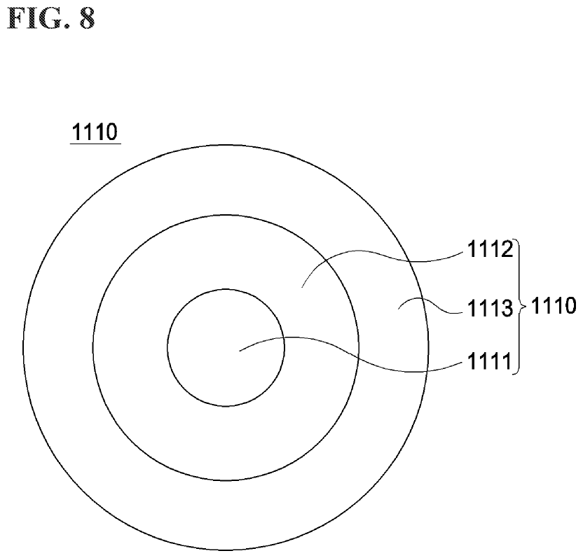

Here, as illustrated in FIG. 8, the temperature adjusting areas may include a first temperature adjusting area 1111 that shares a center with the planar circular temperature adjusting plate 1110 and is divided into a planar circular shape at a position corresponding to the central side of the substrate 1; a third temperature adjusting area 1113 separated from an edge of the temperature adjusting plate 1110; and a second temperature adjusting area 1112 divided between the first temperature adjusting area 1111 and the third temperature adjusting area 1113 area.

That is, the temperature adjusting areas may be divided into areas that are capable of being independently adjustable in temperature according to areas corresponding to the substrate 1, which are opposite to the temperature adjusting plate 1110, and thus, the temperature may be independently adjusted on specific areas.

The rod part 1120 may have a configuration coupled to the temperature adjusting plate 1110 through the top lid 140 and may have various configurations.

Here, the rod part 1120 may have a configuration that supplies various refrigerants or power to the temperature adjusting plate 1110 from the outside by having a hollow defined therein.

For example, the rod part 1120 may include a rod 1121 passing through the top lid 140 and be coupled to the temperature adjusting plate 1110 to support the temperature adjusting plate 1110 and a supply line 1122 inserted into a hollow of the rod 1121 to supply the power or refrigerant to the temperature adjusting plate 1110 from the outside.

The buffer plate 1130 may have a configuration that is coupled to the through-hole 320 at the lower side of the inner lid part 300 to cover the temperature adjusting plate 1110, and may various configurations.

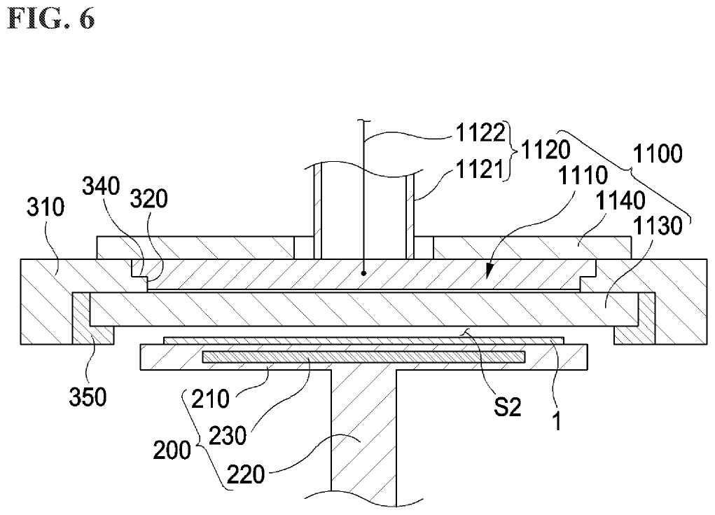

For example, as illustrated in FIG. 6, the buffer plate 1130 may be coupled to the through-hole 320 at the lower side of the inner lid part 300 and be disposed between the temperature adjusting plate 1110 and the substrate 1 to mediate the heat exchange between the temperature adjusting plate 1110 and the substrate 1.

Here, the buffer plate 1130 may be manufactured with a stable design even in high temperature and high pressure environments and may be made of a quartz material.

Thus, the buffer plate 1130 may minimize an influence of the high pressure by preventing the direct exposure of the temperature adjusting plate 1110 to the high pressure environment of the processing space S2 to facilitate the heat exchange while protecting the temperature adjusting plate 1110.

Here, as illustrated in FIG. 2, the buffer plate 1130 may be installed below the through-hole 320 of the inner lid 310, and more specifically, may be supported and installed on the support 350 installed on a lower edge of the through-hole 320 of the inner lid 310.

The cover plate 1140 may have a configuration installed to cover the through-hole 320 at the upper side of the inner lid part 300 and may have various configurations.

For example, the cover plate 1140 may cover the through-hole 320 in which the temperature adjusting plate 1110 of the inner lid 310 is installed in a state in which the rod part 1120 passes therethrough, and an end of the above-described second bellows 650 may be coupled to facilitate the movement of the temperature adjusting plate 1110.

The controller may have a configuration that controls the heating or cooling of the temperature adjusting part 1100.

For example, in consideration of the fact that the temperature of the edge of the substrate 1 is relatively low compared to the central side, for this, the controller may control the third temperature adjusting area 1113 so that the third temperature adjusting area 1113 has a temperature higher than that of the first temperature adjusting area 1111.

In addition, the controller may control the temperature adjusting part 1100 so that the temperature of the substrate 1 or the processing space S2 is constantly maintained while a pressure of the processing space S2 is changed.

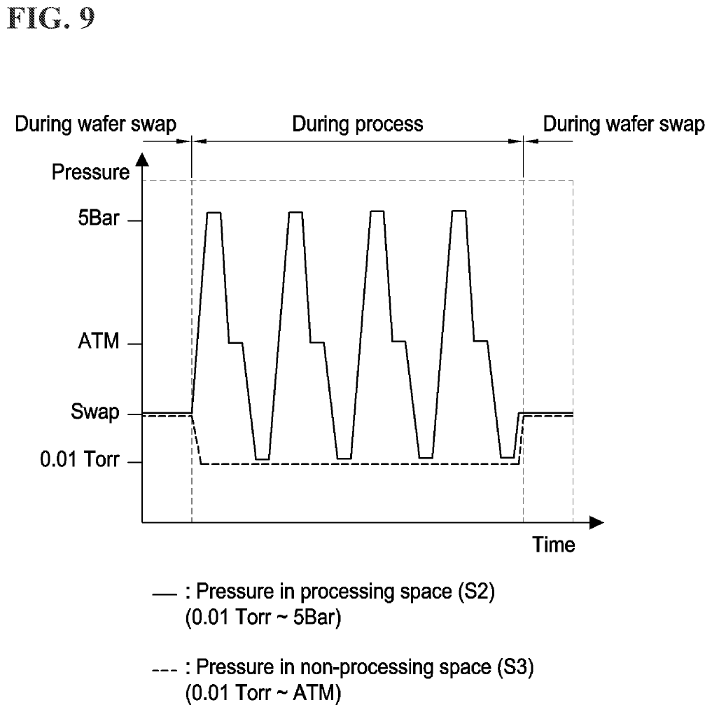

Particularly, as illustrated in FIG. 9, in the substrate processing apparatus according to the present invention, a rapid pressure change may occur in the processing space S2, and thus, the temperature change may rapidly occur due to the pressure change in the processing space S2 in which the substrate 1 is disposed may be performed.

To prevent such a temperature change, the temperature adjusting part 1100 may be controlled so that the temperatures of the substrate 1 and the processing space S2 are constantly maintained.

As described above, when the substrate support 200 is installed in the installation groove 130, a space may be defined between the substrate support 200, more particularly, the substrate support plate 210 and the installation groove 130 to act as a factor that increases in volume of the processing space S2.

To solve this limitation, when the substrate support 200 is installed to be in contact with the installation groove 130, heat supplied through the heater existing in the substrate support 200 may be lost to the process chamber 100 through the bottom surface of the process chamber 100, i.e., the installation groove 130 to cause a heat loss. As a result, it may be difficult to set and maintain the process temperature with respect to the processing space S2, and efficiency may be deteriorated.

To solve this limitation, the filling member 700 according to the present invention may have a configuration that is installed between the substrate support 200 and the bottom surface of the process chamber 100, and may have various configurations.

For example, the filling member 700 may be installed in the installation groove 130, and in the state of being installed in the insulation groove 130, the substrate support plate 210 may be installed at the upper side to minimize a remaining volume between the installation groove 130 and the substrate support plate 210, thereby reducing the volume of the processing space S2.

For this, the filling member 700 may be provided in a shape corresponding to the interspace between the installation groove 130 and the substrate support 200 so that the processing space S2 is minimized.

More specifically, the filling member 700 may have a planar circular shape and may be provided in shape corresponding to the interspace between the installation groove 130, which is defined to have a predetermined depth from the bottom surface 120 with the height difference, and the substrate support plate 210.

That is, the filling member 700 may be installed to be adjacent to at least one of the side surface or the bottom surface of the substrate support plate 210 and may be spaced apart from the substrate support plate 210 to surround the bottom surface and the side surface of the substrate support plate 210.

Here, to prevent the heat from being lost through the filling member 700, the substrate support 200 may be installed to be spaced apart from the filling member 700, and in more detail, the substrate support 200 may be installed with a degree of a fine gap by which the substrate support 200 is not contact with the filling member 700.

As a result, a predetermined distance may be maintained between the substrate support 200 and the filling member 700, and the gap may act as an exhaust passage, and thus, exhaust with respect to the processing space S2 may be performed.

More specifically, the substrate support 200 and the filling member 700 may be installed to be spaced apart from each other to define the exhaust passage. Here, the exhaust passage may communicate with the bottom of the installation groove 130, through which the substrate support post 220 passes, to exhaust the process gas within the processing space S2 to the outside.

The filling member 700 may be made of at least one of quartz, ceramic, or SUS.

In addition, the filling member 700 may not only simply occupy the space between the installation groove 130 and the substrate support 200 to minimize the volume of the processing space S2, but also minimize the loss of the heat transferred to the substrate 1 through the substrate support 200 through thermal insulation and furthermore reflect the heat that is lost to the processing space S2 through thermal reflection.

That is, the filling member 700 may not only minimize the volume of the processing space S2, but also insulate for preventing the heat from being lost through the substrate support 200 to the bottom surface 120 of the process chamber 100, furthermore, perform a reflection function to be improved in thermal efficiency through the reflection of heat.

In addition, to improve the reflection effect of the heat emitted through the substrate support 200 to the processing space S2, a reflection part 720 provided on the surface of the substrate support 200 may be additionally provided.

That is, the filling member 700 may include an insulating part 710 for blocking heat from the processing space S2 to the outside and a reflection part 720 provided on a surface of the insulating part 710 to reflect heat.

Here, the reflection part 720 may be coated, adhered, or applied on the surface of the heat insulating part 710 to provide a reflection layer and may reflect heat lost from the processing space S2 through the process chamber 100 so as to be transferred again to the processing space S2.

In addition, the filling member 700 may further include a first through-hole 731 having a size corresponding to a center so that the foregoing substrate support post 220 is installed and a plurality of second through-holes 732 passing through the plurality of substrate support pins 810 to move vertically.

The substrate support pin part 800 may have a configuration that supports the substrate 1 loaded into or unloaded from the process chamber 100 and is seated on the substrate support 200 and may have various configurations.

For example, the substrate support pin part 800 may include a plurality of substrate support pins 810 passing through the filling member 700 and the substrate support 200 to move vertically, thereby supporting the substrate 1, an annular substrate support ring 820 on which the plurality of substrate support pines 810 are installed, and a substrate support pin driving part 830 that drive the plurality of substrate support pins 810 vertically.

The plurality of substrate support pins 810 may have a configuration that is provided in plurality on the substrate support ring 820 to pass through the filling member 700 and the substrate support 200 so as to move vertically, thereby supporting the substrate 1 and may have various configurations.

Here, the plurality of substrate support pins 810 may be provided in at least three and may be installed to be spaced apart from each other on the substrate support ring 820. Also, the plurality of substrate support pins 810 may ascend to be exposed from the substrate support 200, thereby supporting the substrate 1 that is loaded or may descend to be disposed inside the substrate support 200, thereby seating the substrate 1 on the substrate support 200.

The substrate support ring 820 may have an annular configuration on which the plurality of substrate support pins 820 are installed so that the plurality of substrate support pins 820 move vertically at the same time through the vertical movement.

Particularly, the substrate support ring 820 may be installed in a support pin installation groove 160 defined in the bottom surface of the process chamber 100, that is, the installation groove 130 to move vertically by a substrate support pin driving part 830.

The substrate support pin driving part 830 may have a configuration that is installed outside the process chamber 100 to drive the substrate support ring 820 vertically, and may have various configurations.

For example, the substrate support pin driving part 830 may include a substrate support pin rod 831 that has one end connected to the bottom surface of the substrate support ring 820 and the other end connected to a substrate support pin driving source 833 to move vertically according to driving force of the substrate support pin driving source 833, and a substrate support guide 832 configured to guide linear movement of the substrate support pin rod 831, and a substrate support pin driving source 833 configured to drive the substrate support pin rod 831.

In addition, the substrate support pin part 800 may further include a substrate support bellows 840 that surrounds the substrate support pin rod 831 and is installed between the bottom surface of the process chamber 100 and the substrate support pin driving source 833.

Hereinafter, a substrate processing apparatus according to another embodiment of the present invention will be described with reference to the accompanying drawings, and detailed descriptions of the same configuration as those of the above configurations will be omitted.

Thus, all of the above contents may be equally applied to the configuration in which the redundant description is omitted.

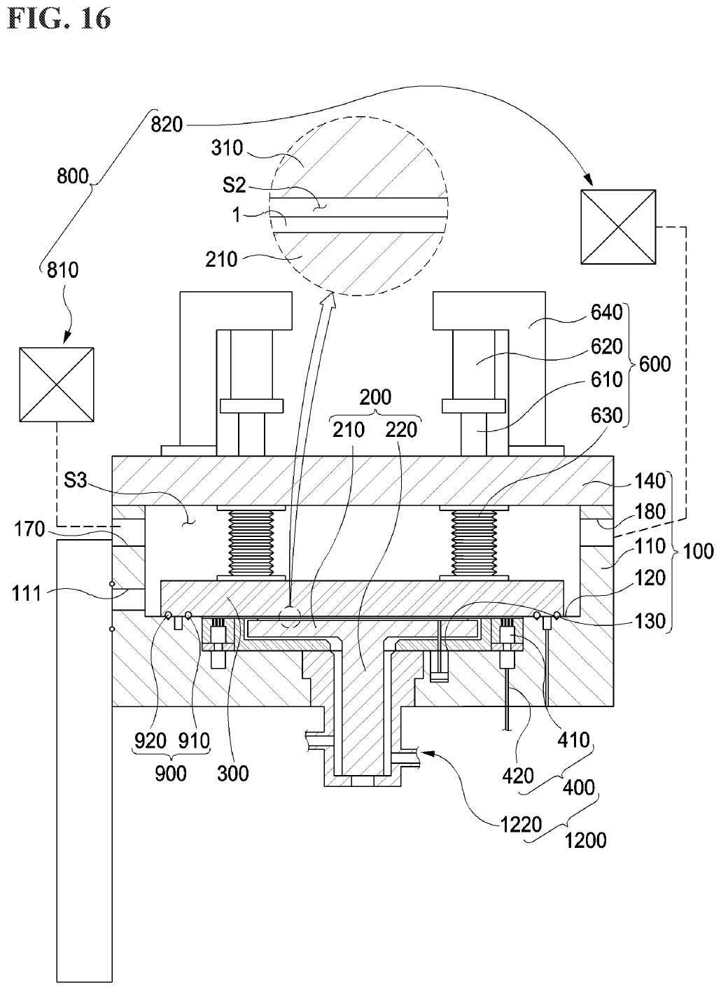

As illustrated in FIG. 16, a substrate processing apparatus according to the present invention includes a process chamber 100 including a chamber body 110 which has an opened upper portion, in which an installation groove 130 is defined at a central side of a bottom surface 120 thereof, and which includes a gate 111 for loading/unloading a substrate 1 is disposed at one side thereof and a top lid 140 coupled to the upper portion of the chamber body 110 to define a non-processing space S3, a substrate support 200 installed to be inserted into the installation groove 130 of the chamber body 110 and having a top surface on which the substrate 1 is seated, an inner lid part 300 which is installed to be vertically movable in the inner space and of which a portion is in close contact with the bottom surface 120 adjacent to the installation groove 130 through descending to define a sealed processing space S2 in which the substrate support 200 is disposed, a first pressure adjusting part 1200 communicating with the processing space S2 to adjust a pressure of the processing space S2; and a second pressure adjusting part 1300 communicating with the non-processing space S3 to adjust a pressure of the non-processing space S3 independently of the processing space S2.

In addition, the substrate processing apparatus according to the present invention may further include an inner lid driving part 600 installed to pass through a top surface of the process chamber 100 so as to drive the vertical movement of the inner lid part 300.

In addition, as illustrated in FIG. 5, the substrate processing apparatus according to the present invention may further include a controller configured to control the pressures of the processing space S2 and the non-processing space S3 through the first pressure adjusting part 1200 and the second pressure adjusting part 1300.

In addition, the process chamber 100 may further include a gas supply hole 170 having one side to which a second gas supply part 1310 to be described later is connected to supply a filling gas to the non-processing space S3.

In addition, the process chamber 100 may further include a gas exhaust hole 180 having the other side to which a second gas exhaust part 1320 is connected to exhaust the non-processing space S3.

The gas supply hole 170 may have a configuration which is provided at one side of the chamber body 110 of the process chamber 100 and to which the second gas supply part 1310 is connected.

For example, the gas supply hole 170 may be defined through processing at one side of the chamber body 110 or may be provided by being installed in a through-hole defined in one side of the chamber body 110.

Thus, in the gas supply hole 170, the second gas supply part 1310 is installed to connect the non-processing space S3 to the second gas supply part 1310, and thus, the filling gas may be supplied to the non-processing space S3.

The gas exhaust hole 180 may have a configuration which is provided at the other side of the chamber body 110 of the process chamber 100 and to which the second gas exhaust part 1320 is connected.

For example, the gas exhaust hole 180 may be defined through processing at the other side of the chamber body 110 or may be provided by being installed in a through-hole defined in the other side of the chamber body 110.

Thus, in the gas exhaust hole 180, the second gas exhaust part 1320 may be installed to exhaust the non-processing space S3.

Here, the inner lid part 300 may cover the installation groove 130 on a plane, and the edge of the inner lid part 300 may have a size corresponding to a portion of the bottom surface 120. In addition, the edge may be in close contact with the bottom surface 120 to define the sealed processing space S2 between the installation groove 130 and the inner lid part 300.

For another example, the edge of the inner lid part 300 may be in close contact with the inner surface of the process chamber 100 to define the processing space S2.

In addition, to effectively achieve and maintain the process temperature in the sealed processing space S2 defined according to the vertical movement, the inner lid part 300 may be made of a material having an excellent thermal insulation effect that is capable of preventing the temperature of the processing space S2 from being lost to the inner space.

That is, the inner lid part 300 may be installed to be movable vertically in the inner space S1, and a portion of the inner lid part 300 may be in close contact with the bottom surface 120 adjacent to the installation groove 130 through the descending to divide the inner space S1 into the processing space S2, in which the substrate support 200 is disposed, and other non-processing space S3.

As a result, the inner lid part 300 may be in close contact with the bottom surface 120 through the descending of the inner space S1 inside the process chamber 100 to divide the inner space S1 into the sealed processing space S2, in which the substrate support part 200 is disposed, and other non-processing space S3, and the processing space S2 and the non-processing space S3 may communicate with each other through ascending.

The first pressure adjusting part 1200 may have a configuration that communicates with the processing space S2 to adjust the pressure in the processing space S2 and may have various configurations.

For example, the first pressure adjusting part 1200 may include a gas supply part 400 configured to supply the process gas to the processing space S2 and a gas exhaust part 1220 configured to exhaust the processing space S2.

That is, the first pressure adjusting part 1200 may supply the process gas to the processing space S2 and adequately exhaust the processing space S2 to adjust the pressure of the processing space S2. Thus, as illustrated in FIG. 9, high-pressure and low-pressure pressure atmospheres may be repeatedly changed and created within a short time in the processing space S2.

Here, more specifically, the pressure of the processing space S2 may be repeatedly changed at a pressure change rate of about 1 Bar/s in a pressure range of about 5 Bars to about 0.01 Torrs.

Particularly, in this case, the first pressure adjusting part 1200 may fall the pressure of the processing space S2 from a first pressure to a normal pressure, and thus, the pressure of the processing space S2 may decrease step by step from the normal pressure to a second pressure.

In addition, the first pressure adjusting part 1200 may sequentially and repeatedly change the pressure of the processing space S2 from the first pressure to the second pressure and then to the first pressure several times to perform the substrate processing.

The gas supply part 400 may have a configuration that supplies the process gas in communication with the processing space S2, and the above-described configuration may be applied in the same manner, and thus a detailed description thereof will be omitted.

The gas exhaust part 1220 may have a configuration that exhausts the processing space S2, and may have various configurations.

For example, the gas exhaust part 1220 may include an external exhaust device communicating with the processing space S2 and installed outside, and thus, an exhaust amount to processing space S2 may be controlled to adjust the pressure of the processing space S2.

The first pressure adjusting part 1300 may have a configuration that communicates with the processing space S2 to adjust the pressure in the processing space S2 and may have various configurations.

Particularly, the second pressure adjusting part 1300 may adjust the pressure in the non-processing space S3 defined separately from the processing space S2 independently of the processing space S2.

For example, the second pressure adjusting part 1300 may include a second gas supply part 1310 communicating with the non-processing space S3 to supply a filling gas to the non-processing space S3 and a second gas exhaust part 1320 performing exhaust for the non-processing space S3.

The second gas supply part 1310 may be connected to the above-described gas supply hole 170 to supply the filling gas to the non-processing space S3, and thus, the pressure to the non-processing space S3 may be adjusted.

The second gas exhaust part 1320 may be connected to the above-described gas exhaust hole 180 to exhaust the non-processing space S3, and thus, the pressure of the non-processing space S3 may be adjusted.

Any configuration may be applied to the second gas supply part 1310 and the second gas exhaust part 1320 as long as the second gas supply part 1310 and the second gas exhaust part 1320 are configured to supply and exhaust the filling gas that is disclosed in the related art.

In the process of changing the pressure of the processing space S2, in which the substrate 1 is seated, from the first pressure higher than the normal pressure to the second pressure, the second pressure adjusting part 1300 may be configured to constantly maintain the pressure in the non-processing space S3.

Here, the second pressure adjusting part 1300 may maintain the pressure of the non-processing space S3 as vacuum while the substrate processing is performed, and in this process, the pressure of the processing space S2 may be less than or equal to that of the processing space S2.

That is, the second pressure adjusting part 1300 may constantly maintains the pressure of the non-processing space S3 at a pressure of about 0.01 Torrs, which is the second pressure, in the substrate processing process, to maintain the pressure so as to be equal to or less than that of the processing space S2. As a result, impurities may be prevented from being introduced from the non-processing space S3 into the processing space S2.

For another example, the second pressure adjusting part 1300 may change the pressure of the non-processing space S3, and in this process, the pressure of the non-processing space S3 may have a pressure value less than that of the processing space S2.

In addition, the second pressure adjusting part 1300 may adjust the pressure of the non-processing space S3 through only the exhaust without supplying the filling gas to the non-processing space S3 during the substrate processing process.

That is, the second pressure adjusting part 1300 may adjust the pressure of the non-processing space S3 through only an operation of the second gas exhaust part 1320 without suppling the filling gas according to the second gas supply part 1310.

For another example, the second pressure adjusting part 1300 may supply the filling gas to the non-processing space S3, and the pressure of the non-processing space S3 may be adjusted together with the exhaust of the second gas exhaust part 1320.

Unlike the above, the second pressure adjusting part 1300 may include a gas supply hole 170 transferring the filling gas supplied from the outside and a gas exhaust hole 180 exhausting the non-processing space S3 as a gas exhaust hole 180 defined in one side of the process chamber 100, i.e., the chamber body 110, and a gas supply hole 170 defined in the other side.

The controller may have a configuration that controls the pressure adjustment of the processing space S2 and the non-processing space S3 through the first pressure adjusting part 1200 and the second pressure adjusting part 1300.

Particularly, in connection with the process of the substrate processing, the controller may perform the control through the first pressure adjusting part 1200 and the second pressure adjusting part 1300 of the non-processing space S3 and the processing space S2 in each process.

For example, the controller may supply a purge gas through the gas supply part 400 to supply the purge gas through the gas supply part 400 and exhaust the purge gas through the second gas exhaust part 1320 in a state in which the inner lid part 300 ascends to allow the processing space S2 and the non-processing space S3 communicate with each other.

More specifically, to perform cleaning of the processing space S2 in which the substrate processing is performed, the controller may supply the purge gas through the gas supply part 400 to clean or purge a surrounding of the substrate support 200, in which the substrate processing is performed, in a state in which the inner lid part 300 ascends so that the processing spaced S2 and the non-processing space S3 communicate with each other.

Furthermore, the purge gas may be exhausted through the second gas exhaust part 1320 provided on the side surface of the process chamber 100 to induce an upward flow of the purge gas supplied through the gas supply part 400 to the side surface, thereby inducing internal floating matters to be exhausted to the non-processing space S3 and the outside.

In addition, before ascending of the inner lid part 300, the controller may control the pressure so that the pressures of the processing space S2 and the non-processing space S3 are the same through at least one of the first pressure adjusting part 1200 or the second pressure adjusting part 1300.

More specifically, the controller may control the pressure so that the pressures of the processing space S2 and the non-processing space S3 are the same through at least one of the first pressure adjusting part 1200 or the second pressure adjusting part 1300 to prevent the substrate 1 from being changed in position or damaged due to a pressure difference between the non-processing space S3 and the processing space S2 before the substrate processing is performed in a state in which the inner lid part 300 descends to define the sealed processing space S2, and the inner lid part 300 ascends to unload the processed substrate 1.

That is, when the non-processing space S3 and the processing space S2 communicate with each other due to the ascending of the inner lead part 300 while the pressure difference between the non-processing space S3 and the processing space S2 is maintained, in order to prevent the substrate 1 from being affected by the generation of the airflow in one direction due to the pressure difference, the controller may control at least one of the first pressure adjusting part 1200 and the second pressure adjusting part 1300 so that the pressures of the non-processing space S3 and the processing space S2 are the same.

Hereinafter, a substrate processing method using the substrate processing apparatus according to the present invention will be described with reference to the accompanying drawings.

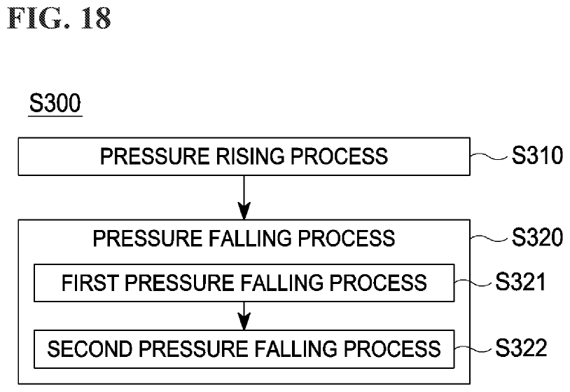

As illustrated in FIGS. 16 to 18, a the substrate processing method according to the present invention includes a substrate loading process (S100) of loading a substrate 1 into an inner space S1 through a gate 111 by a transfer robot provided at the outside to seat the substrate 1 on a substrate support 200, a processing space forming process (S200) of allowing a portion of the inner lid part 300 to descend so as to be in close contact with a bottom surface 120 of the process chamber in a state in which the substrate 1 is seated on the substrate support 200 through the substrate loading process (S100), thereby dividing the inner space into a sealed processing space S2 and other non-processing space S3, and a substrate processing process (S300) of performing substrate processing on the substrate 1 disposed in the processing space S2.

In addition, the substrate processing method may further include, after the substrate is processed through the substrate processing process (S300), a processing space releasing process (S400) of allowing the inner lid part 300 to ascend so as to release the sealed processing space S2; and a substrate unloading process (S500) of unloading the processed substrate 1 by the transfer robot, which is disposed at the outside, from the inner space S to the outside.

In addition, the substrate processing method may further include, before the substrate 1 is loaded into the inner space through the substrate loading process (S100), a cleaning process of supplying the process gas through a side of the processing space S2 in the state in which the inner lid part 300 ascends to exhaust the process gas through a side of the non-processing space S3.

The substrate loading process (S100) may be a process of loading the substrate 1 into the inner space through the gate 111 by the transfer robot provided at the outside to seat the substrate 1 on the substrate support 200 and may be performed through various methods.

That is, in the substrate loading process (S100), the substrate 1 to be processed may be loaded into the inner space S1 through the external transfer robot and seated on the substrate support 200, thereby preparing the processing for the substrate 1.

For example, the substrate loading process (S100) may include, before the loading process, a loading pin-up process of allowing substrate support pins 810 to ascend to an upper side of the substrate support 200 in a state in which the inner lead part 300 ascends.

In addition, the substrate loading process (S100) may include a loading process of loading the substrate 1 into the inner space through the gate 111 by the transfer robot provided at the outside to support the substrate 1 on the ascending substrate support pins 810 and a loading pin-down process of allowing the substrate support pins 810 supporting the substrate to descend, thereby seating the substrate 1 on the substrate support 200.

The loading pin-up process may be a process of allowing the substrate support pins 810 to ascend to an upper side of the substrate support 200 in the state in which the inner lid part 300 ascends, i.e., in the state in which the processing space S2 is released.

In this case, in the loading pin-up process, the substrate processing may be repeatedly performed on the plurality of substrates 1. When the substrate 1 is loaded initial one time, thereafter, the substrate 1 on which the substrate process is completed may have to be unloaded in the state in which an unload according to an unloading pin-up process to be described later, and then, the loading process may be immediately followed and thus may be omitted.

As a result, the loading pin-up process may be performed in a situation in which the substrate 1 is initially loaded into the substrate processing apparatus and may be omitted thereafter.

The loading process may be a process of loading the substrate 1 into the inner space S1 through the gate 111 by the transfer robot provided at the outside to support the substrate through the substrate support pins 810.

More specifically, in the loading process, in the state in which the substrate 1 supported by the transfer robot provided at the outside is loaded into the inner space S1 through the gate 111, the transfer robot may descend to support the substrate 1 on the substrate support pins 810, and the external robot may be carried out of the inner space S1.

For another example, in the state in which the substrate 1 supported by the transfer robot provided at the outside is loaded into the inner space S1 through the gate 111, the substrate support pins 810 may ascend to support the substrate 1 on the substrate support pins 810, and the external robot may be carried out.

In the loading pin-down process, the substrate support pins 810 supporting the substrate 1 may descend to allow the substrate support 200, more particularly, the substrate support pines 810 to be inserted into a substrate support plate 210 so that the substrate 1 is seated on a top surface of the substrate support plate 210.

The processing space forming process (S200) may be a process of allow an inner lid part 300 to descend so that a portion of the inner lid part 300 is in close contact with a bottom surface 120 of the process chamber 100 in the state in which the substrate 1 is seated on the substrate support 200 through the substrate loading process (S100), thereby dividing the inner space S1 into the sealed processing space S2 and other non-processing space S3 and may be performed through various methods.

For example, in the processing space forming process (S200), the inner lid part 300 may descend in the state in which the substrate 1 is seated on the substrate support 200 to allow the bottom surface 120 and an edge of the process chamber 100 to be in close contact with each other, thereby forming the sealed processing space S2. Here, to form the sealed processing space S2, a sealing part 320 of the inner lid part 300 may be in close contact with the bottom surface 120.

As a result, in the processing space forming process (S200), the sealed processing space S2 may be separately formed to be separated from the inner space S1, and in the state in which the substrate 1 is disposed therein, a volume of the processing space S2 may be formed to be minimized.

Furthermore, in the processing space forming process (S200), the inner lid part 300 may descend to allow the inner space S1 to be in close contact with a portion of the bottom surface 120 of the process chamber 100, and thus, the inner space may be divided into the sealed processing space S2 and other non-processing space S3.

Thus, the limitation in which the substrate processing is performed in the state in which the inner space is formed at a high pressure according to the related art, and thus, the gate valve is damaged may be prevented from occurring. In addition, a kind of buffer space may be formed in the non-processing space S3 between the processing space S2 and the gate valve to prevent the gate valve from being damaged even in the high-pressure substrate processing.

The substrate processing process S300 may be a process of performing the substrate processing on the substrate 1 disposed in the processing space S2 and may be performed through various methods.

In this case, in the substrate processing process (S300), the process gas may be supplied into the sealed processing space S2 through the gas supply part 400 to adjust and control a pressure within the processing space S2.

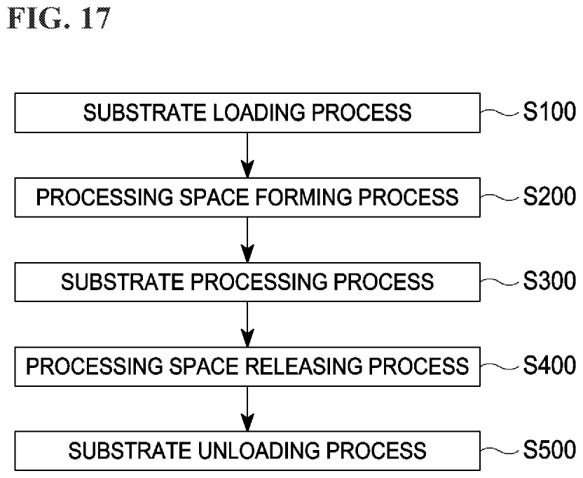

Particularly, in the substrate processing process (S300), as illustrated in FIG. 17, a pressing process of rising the pressure of the processing space S2 through the process gas, and a decompression process of falling the pressure of the processing space S2 after the pressing process may be performed.

Here, in the substrate processing process (S300), the pressure may increase to a pressure higher than the normal pressure, for example, a high pressure of about 5 bars, and the pressure may be decrease to a pressure lower than the normal pressure, for example, a low pressure of about 0.01 torrs.

In this case, in the substrate processing process (S300), the pressing process and the decompression process may be repeatedly performed within a short time.

More specifically, the substrate processing process (S300) may include a pressure rising process (S310) of raising a pressure in the processing space S2 to a first pressure higher than a normal pressure, and a pressure falling process (S320) of falling the pressure of the processing space S2 from the first pressure to a second pressure.

In addition, in the substrate processing process (S300), the pressure rising process (S310) and the pressure falling process (S320) may be repeatedly performed several times as one unit cycle, thereby performing repeated pressure change in the processing space S2.

In this case, the second pressure may be a pressure lower than the normal pressure, and the first pressure may be a pressure higher than the normal pressure.

The pressure falling process (S320) may include: a first pressure falling process (S321) of falling the pressure of the processing space S2 from the first pressure to the normal pressure, and a second pressure falling process (S322) of falling the pressure of the processing space S2 from the normal pressure to the second pressure lower than the normal pressure.

Thus, in the pressure falling process (S320), the pressure may be decrease step by step through the first pressure falling process (S321) of falling the pressure of the processing space S2 from the first pressure, which is higher than the normal pressure, to the normal pressure, and the second pressure falling process (S322) of falling the pressure of the processing space S2 from the normal pressure to the second pressure lower than the normal pressure.

In addition, in the substrate processing process (S300), the pressure of the non-processing space S3 may be constantly maintained at a vacuum pressure lower than the normal pressure during the pressure change process in the processing space S2.

The processing space releasing process (S400) may be a process of releasing the sealed processing space S2 by allowing the inner lid part 300 to ascend after the substrate processing through the substrate processing process (S300) and may be performed through various methods.

Here, in the processing space releasing process (S400), the inner lid part 300 may ascend through the above-described inner lid driving part 600 to release the contact with the bottom surface 120 of the process chamber 100 so that the inner space and the processing space S2 communicate with each other, thereby releasing the sealed processing space S2.

In this case, when the inner lid part 300 ascends in the state in which the pressure difference between the processing space S2 and the non-processing space S3 is large, durability of the substrate 1 may be damaged due to the pressure difference between the two spaces, and thus, it is necessary to minimize the pressure difference between the two spaces.

For this, the processing space releasing process (S400) may include: a pressure adjusting process (S410) of adjusting a pressure of at least one of the non-processing space S3 or the processing space S2 to adjust a pressure difference between the non-processing space S3 and the processing space S2 to a pressure below a preset range; and an inner lid ascending process (S420) of allowing the inner lid part 300 to ascend so as to release the processing space S2.

Here, in the pressure adjusting process (S410), the pressure of the non-processing space S3 may be adjusted through an exhaust part (not shown) for exhausting the gas supply part 400 or the processing space S2 to reduce the pressure difference between the processing space S2 and the non-processing space S3. Alternatively, the gas may be injected into the non-processing space S3 to reduce the pressure difference between the processing space S2 and the non-processing space S3 to a predetermined level or less.

In this case, in the pressure adjusting process (S410), a process of adjusting at least one pressure of the processing space S2 and the non-processing space S3 may be performed so that the pressure difference between the processing space S2 and the non-processing space S3 has a value within a predetermined range.

Particularly, when the inner lid part 300 ascends in the high-pressure processing space S2 and the vacuum non-processing space S3, a limitation in which slip of the substrate 1 occurs due to the large pressure difference between the spaces may occur. Thus, the inner lid part 300 may ascend in the state in which the pressures therebetween are adjusted to be the same.

The substrate unloading process (S500) may be a process of unloading the substrate 1, on which the substrate processing is completed, from the inner space S1 to the outside through the gate 111 by the transfer robot provided at the outside and may be performed through various methods.

That is, in the substrate unloading process (S500), the processed substrate 1 may be transferred from the substrate support 200 through the external transfer robot and unloaded from the inner space S1.

For example, the substrate unloading process (S500) may include an unloading pin-up process of allow the substrate support pins 810 to ascend so that the substrate 1 seated on the substrate support 200 is spaced upward from the substrate support 200, thereby supporting the substrate support pin 810 and a unloading process of unloading the substrate 1, on which the substrate processing is completed, from the inner space S1 to the outside through the gate 111 by the transfer robot provided at the outside.

In addition, the substrate unloading process (S500) may further include an unloading pin-down process of allow the substrate support pins 810 to descend into the substrate support 200 after the unloading process to be described later.

The unloading pin-up process may be a process of allowing the substrate support pins 810 to ascend to an upper side of the substrate support 200 in a state in which the inner lid part 300 ascends, i.e., in a state in which the processing space S2 is released.

Thus, in the unloading pin-up process, the processed substrate 1 seated on a top surface of the substrate support 200 may move and be exposed upward from the substrate support plate 210 so that the substrate 1 is supported to be spaced upward from the substrate support plate 210.

An unloading process may be a process of unloading the substrate 1 on which the substrate processing is completed by the transfer robot provided at the outside from the inner space S1 through the gate 111 to the outside.

More specifically, in the unloading process, the substrate 1 supported by the substrate support pins 810 may be supported by the transfer robot introduced into the inner space S1 through the gate 111, and the supported substrate 1 may be unloaded to the outside.

For this, in the unloading process, the transfer robot may be disposed below the substrate 1 in the state where the processed substrate 1 is supported by the substrate support pins 810, and the transfer robot may ascend to allow the transfer robot to support the substrate 1.

For another example, in the unloading process, the transfer robot may be disposed below the substrate 1 in the state in which the processed substrate 1 is supported by the substrate support pins 810, and the substrate support pins 810 may descend to allow the substrate 1 to be disposed on the transfer robot.

As described above, as the transfer robot moves to the outside through the gate 111 in the state in which the substrate 1 is supported by the transfer robot, the substrate 1 on which the substrate processing is completed may be unloaded.

In the unloading pin-down step, the substrate support pins 810 supporting the substrate 1 may descend to insert the substrate support pins 810 into the substrate support 200, more specifically, the substrate support plate 210.

Here, the unloading pin-down process may be performed after the substrate processing for the plurality of substrates 1 is repeatedly performed, and may also be performed after the last one substrate is unloaded. Previously, since it is necessary to maintain the state in which the substrate support pins 810 ascend to perform the above-described loading process, and thus, it may be omitted.

As a result, the unloading pin-down process may be performed in a situation in which the last substrate 1 is unloaded from the substrate processing apparatus, or in a situation in which the substrate processing apparatus is maintained and repaired in the middle.

The above-described substrate loading process (S100), the processing space forming process (S200), the substrate processing process (S300), the processing space releasing process (S400), and the substrate unloading process (S500) may be sequentially and repeatedly performed several times in one cycle (S10), and thus, one cycle may be performed to correspond to one substrate 1.

For another example, the substrate processing method according to the present invention may include, after the processing space forming process (S200), a gate closing process of closing the gate 111 through the gate valve 150 to seal the inner space S1.

In addition, the substrate processing method according to the present invention may further include, before the substrate loading process (S100), a gate opening process of opening the gate 111 through the gate valve 150.

In addition, the substrate processing method according to the present invention may further include, after the processing space releasing process (S400), a gate opening process of opening the gate 111 through the gate valve 150.

In addition, the substrate processing method according to the present invention may further include, after the loading process (S500), a gate closing process of closing the gate 111 through the gate valve 150.

The gate closing process may be a process of closing the gate 111 through the gate valve 150 to seal the inner space S1.

Here, in the gate closing process, the inner space may be sealed after the processing space forming process (S200). In this case, for another example, before the processing space forming process (S200) and after the substrate loading process (S100), the gate closing process may be performed.

That is, in the substrate processing method according to the present invention, since the processing space S2 is selectively formed separately in the inner space S1 as necessary, the closing of the gate 111 through the gate valve 150 may be performed independently of the formation of the processing space S2.

That is, according to the formation of the processing space S2 of the inner lid part 300, the closing of the gate 111 through the gate valve 150 may be performed as necessary.

The gate closing process of closing the gate 111 through the gate valve 150 may be performed for a separate pressure control of the inner space and may be performed after the processing space forming process (S200).

In addition, the gate closing process may be performed to close the gate 111 after the unloading process S500. In this case, the gate closing process may be omitted in the process of repeatedly performing the substrate processing on the plurality of substrates 1 and may be performed only when the substrate processing is completely performed on the last substrate, or only when the maintenance and repair of the substrate processing apparatus are required.

The gate opening process may be a process of opening the gate 111 through the gate valve 150.

In this case, in the gate opening process, the opening of the inner space may be performed after the processing space releasing process (S400), and in this case, for another example, before the processing space releasing process (S400) and after the substrate processing process (S300), the gate closing process may be performed.

Thus, the gate opening process may be performed before the substrate unloading process (S500), and thus, the substrate 1 on which the substrate processing is completed may be unloaded to the outside.

In addition, the gate opening process may be performed to open the gate 111 before the substrate loading process S100. In this case, the gate opening process may be omitted in the process of repeatedly performing the substrate processing on the plurality of substrates 1 and may be selectively performed only when the initial substrate is loaded, or only when the maintenance and repair of the substrate processing apparatus are required.

The cleaning process may be a process of supplying the gas through a side of the processing space S2 in the state in which the inner lid part 300 ascends to exhaust the gas through a side of the non-processing space S3 before the substrate 1 is loaded into the inner space through the substrate loading process (S100).

More specifically, the cleaning process may be a process of cleaning the inner space S1 including the processing space S2 in which the substrate processing is performed before loading the substrate 1 into the inner space through the substrate loading process (S100), and after unloading the substrate 1 from the inner space through the substrate unloading process (S500).

Here, in the cleaning process, the exhaust may be performed through a gas exhaust hole (not shown) at a side of the non-processing space S3, and a cleaning gas may be injected through the gas supply part 400 at a side of the processing space, and thus, a purge gas may be discharged through the gas exhaust hole of the non-processing space S3 via the processing space S2.

That is, in this case, the gas may mean various types of gases such as the process gas for the substrate processing, the cleaning gas for cleaning the inside of equipment, and the purge gas for purging the inner space S1. Here, the cleaning gas may be injected through the processing space-side gas supply part 400, and the purge gas may be discharged through the gas exhaust hole of the non-processing space S3.

Therefore, in the cleaning process, a flow of the cleaning gas may be induced from the processing space S2 to the non-processing space S3 to more completely clean the inner space S1, particularly an area corresponding to the processing space S2.

The substrate processing apparatus according to the present invention may have the advantage of improving the pressure change rate in the wide pressure range by minimizing the volume of the pressing space in which the substrate inside the chamber is processed.

Particularly, the substrate processing apparatus according to the present invention may have the advantage that the volume of the processing space, in which the substrate is processed, is minimized to change the pressure at the high pressure change rate of about 1 Bar/s from the low pressure of about 0.01 Torrs to the high pressure of about 5 Bars.

Particularly, the substrate processing apparatus according to the present invention has the advantage of being able of minimizing the volume of the processing space in which the substrate is processed while easily loading and unloading the substrate.

In addition, the substrate processing apparatus according to the present invention may have the advantage of preventing the foreign substances such as the gas from leaking through the installation of the sealing part and preventing the sealing part from corroding and being damaged through the purge with respect to the sealing part, thereby improving the durability.

In addition, the substrate processing apparatus according to the present invention may have the advantage of effectively removing the foreign substances and the impurities from the substrate through the rapid pressure change to improve the substrate processing rate.

In addition, the substrate processing apparatus according to the present invention may have the advantage that the substrate processing is performed by forming the sealed processing space through the descending adhesion of the inner lid part irrespective of the gate valve even when processing the substrate through the high-pressure process to facilitate the performing of the substrate processing in the high-pressure process and prevent the gate vale from being damaged.

In addition, the substrate processing apparatus according to the present invention may have the advantage of preventing the leakage to the outside of the apparatus through the pumping in the inner space due to the formation of the double space even when the risk occurs from the processing space during the substrate processing according to the high-pressure process.

In addition, the substrate processing apparatus according to the present invention may have the advantage of minimizing the volume of the processing space in which the substrate is processed, to improve the pressure change rate in the wide pressure range, thereby enabling the precise temperature control in response to the temperature change of the substrate.

Particularly, the substrate processing apparatus according to the present invention has the advantage of improving the process effect and forming the uniform film quality by controlling the temperature of the substrate to be constantly maintained even in the case of the temperature change factor caused by the sudden change in pressure.

In addition, since the substrate processing apparatus according to the present invention may have the advantage of directly performing the heating or cooling at the upper side that corresponds to the substrate processing surface so that the temperature compensation is fast to quickly and precisely control the temperature of the substrate.

In addition, the substrate processing apparatus according to the present invention may have the advantage of injecting the uniform gas through the gas injection part provided at the position adjacent to the substrate in the minimized processing space to improve the local temperature and processing deviation of the substrate, thereby realizing the uniform substrate processing.

Although the above description merely corresponds to some exemplary embodiments that may be implemented by the present invention, as well known, the scope of the present invention should not be interpreted as being limited to the above-described embodiments, and all technical spirits having the same basis as that of the above-described technical spirit of the present invention are included in the scope of the present invention.

What is claimed is:

1. A substrate processing apparatus comprising:
a process chamber comprising a chamber body which has an opened upper portion, in which an installation groove is defined at a central side of a bottom surface thereof, and which comprises a gate configured to load/unload a substrate is disposed at one side thereof, and a top lid coupled to the upper portion of the chamber body to define an inner space;
a substrate support installed to be inserted into the installation groove of the chamber body and having a top surface on which the substrate is seated;
an inner lid part which is installed to be vertically movable in the inner space and of which a portion is in close contact with the bottom surface adjacent to the installation groove through descending to define a sealed processing space in which the substrate support is disposed;
a gas supply part installed to communicate with the processing space and configured to supply a process gas to the processing space; and
an inner lid driving part installed to pass through the top lid to drive the vertical movement of the inner lid part.

2. The substrate processing apparatus of claim 1, wherein the bottom surface is disposed higher than a top surface of the substrate seated on the substrate support.

3. The substrate processing apparatus of claim 2, wherein the installation groove is provided in a shape corresponding to the substrate support installed so that the processing space is minimized.

4. The substrate processing apparatus of claim 2, wherein the substrate support comprises:
a substrate support plate which has a planar circular shape and on which the substrate is seated on the top surface thereof; and
a substrate support post passing through a bottom surface of the installation groove so as to be connected to the substrate support plate,
wherein the installation groove has a shape corresponding to the substrate support plate to minimize a remaining space except for a space in which the substrate support plate is installed.

5. The substrate processing apparatus of claim 1, wherein the gas supply part is installed adjacent to an edge of the substrate support.

6. The substrate processing apparatus of claim 5, wherein the processing space is defined between a portion of the bottom surface of the inner lid part and the top surface configured to connect the gas supply part to the substrate support.

7. The substrate processing apparatus of claim 1, wherein the gas supply part comprises:
a gas injection part defining a first diffusion space in which the process gas is diffused; and
a plurality of gas injection holes defined in the gas injection part to inject the process gas to the processing space.

8. The substrate processing apparatus of claim 7, wherein the gas injection part is provided in an annular shape to be installed along an edge of the substrate support.

9. The substrate processing apparatus of claim 7, wherein the process chamber comprises a supply passage provided to pass through the bottom surface so as to communicate with the first diffusion space and configured to transfer the process gas to the first diffusion space from the outside, and
the gas injection part comprises a first diffusion groove for the first diffusion space in a bottom surface thereof to communicate with the supply passage.

10. The substrate processing apparatus of claim 7, wherein the gas injection holes are defined in a top surface of the gas injection part.

11. The substrate processing apparatus of claim 7, further comprising a gas diffusion part that is disposed between the gas supply part and the process chamber to diffuse the process gas transferred to the gas supply part by providing a second diffusion space.

12. The substrate processing apparatus of claim 11, wherein the gas diffusion part comprises a second diffusion groove defined in a bottom surface of the gas diffusion part to define the second diffusion space together with the process chamber.

13. The substrate processing apparatus of claim 11, wherein the gas injection part is installed on the top surface of the gas diffusion part to define the first diffusion space together with the top surface of the gas diffusion part, and
the gas diffusion part comprises at least one gas transfer hole defined in the top surface to transfer the process gas from the second diffusion space to the first diffusion space.

14. The substrate processing apparatus of claim 1, further comprising a temperature adjusting part installed in the inner lid part to adjust a temperature of the substrate disposed in the processing space.

15. The substrate processing apparatus of claim 14, wherein the substrate support comprises:
a substrate support plate on which the substrate is seated on a top surface;
a substrate support post passing through the bottom of the installation groove so as to be connected to the substrate support plate; and
an internal heater installed inside the substrate support plate.

16. The substrate processing apparatus of claim 14, wherein the temperature adjusting part comprises:
a temperature adjusting plate installed in the inner lid part to heat or cool the substrate; and
a rod part passing through the top lid so as to be coupled to the temperature adjusting plate.

17. The substrate processing apparatus of claim 16, wherein the temperature adjusting plate is installed in a through-hole defined at a central side of the inner lid part corresponding to the substrate.

18. The substrate processing apparatus of claim 17, wherein the temperature adjusting part further comprises a buffer plate configured to cover the through-hole at a lower side of the inner lid part.

19. The substrate processing apparatus of claim 16, wherein the temperature adjusting plate comprises at least two temperature adjusting areas, which are separated from each other on a plane and are independently adjustable in temperature with respect to each other.

20. The substrate processing apparatus of claim 14, further comprises a controller configured to control the heating or cooling of the temperature adjusting part,
wherein the controller controls the temperature adjusting part so that the temperature of the substrate or the processing space is constantly maintained while a pressure of the processing space is changed.
